(19) United States
(12) Patent Application Publication
(10) Pub. No.: US 2025/0188262 A1
(43) Pub. Date: Jun. 12, 2025

(54) RESIN COMPOSITION AND ARTICLE MADE THEREFROM

(71) Applicant: Elite Electronic Material (KunShan) Co., Ltd., Kunshan City (CN)

(72) Inventors: Jun DU, Kunshan City (CN); Rongtao WANG, Kunshan City (CN); Xueyan JIANG, Kunshan City (CN)

(21) Appl. No.: 18/438,233

(22) Filed: Feb. 9, 2024

(30) Foreign Application Priority Data
Dec. 7, 2023 (CN) 202311671393.4

(51) Int. Cl. C08L 53/00; C08J 5/24; C08L 25/16; H05K 1/03

(52) U.S. Cl. CPC C08L 53/00; C08J 5/244; C08L 25/16; C08J 2325/16; C08J 2353/00; C08J 2425/16; C08J 2435/02; H05K 1/0366; H05K 1/0373

(57) ABSTRACT

A resin composition and an article made therefrom are provided. The resin composition includes: (A) 100 parts by weight of a copolymer, the copolymer having a structural unit formed by a monomer of Formula (1) and a structural unit formed by a monomer of Formula (2), and the content of the structural unit formed by the monomer of Formula (2) in the copolymer is 55 wt % to 90 wt %; and (B) 1 part by weight to 15 parts by weight of a compound of Formula (3). The resin composition may be used to make various articles, such as a prepreg, a resin film, a laminate or a printed circuit board, and at least one of the following improvements can be achieved, including glass transition temperature, storage modulus decay rate, reflow warpage magnitude, percent of thermal expansion in Z-axis, dissipation factor and laminate appearance.

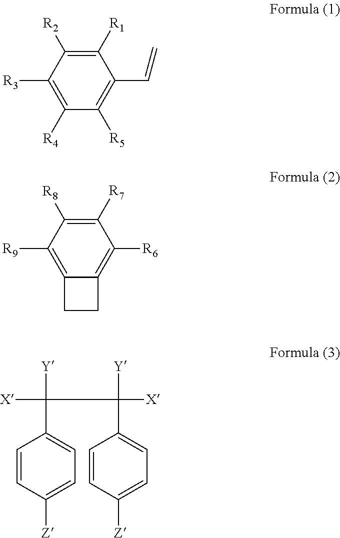

### CROSS-REFERENCE TO RELATED APPLICATION

This application claims the priority benefits of China Patent Application No. 202311671393.4, filed on Dec. 7, 2023. The entirety of the above-mentioned patent application is hereby incorporated by reference herein and made a part of this specification.

### BACKGROUND

### 1. Field of the Disclosure

The present disclosure mainly relates to a resin composition and an article made therefrom, more particularly to a resin composition useful for preparing a prepreg, a resin film, a laminate (e.g., a copper-clad laminate) and a printed circuit board, and an article made therefrom.

### 2. Description of Related Art

Printed circuit board (PCB), as a basic electronic component, is used in many fields such as mobile phones, computers, communication base stations, data centers, automobiles, industrial control, aerospace, etc., the technical level thereof and reliability having direct impacts on performance and stability of electronic equipment. Copper-clad laminate (CCL), as a laminate material of PCB, mainly plays the role of the interconnection and conduction, insulation and support for PCB, and has great influences on the transmission rate, energy loss and characteristic impedance of signals in circuits. The properties of PCB, such as performance, quality, processability, reliability, stability, etc., depend on the performance and quality of copper-clad laminates to a large extent.

The current problems of process capability, signal integrity, heat dissipation and stress are faced by advanced PCB packaging technology, presenting more challenges to the performance of copper-clad laminates, including not only higher glass transition temperature and better laminate appearance, but also lower percent of thermal expansion in Z-axis, a smaller reflow warpage magnitude, lower storage modulus decay rate and lower dissipation factor. However, the existing copper-clad laminates and the resin compositions used in the preparation thereof still mainly focus on the general characteristics of copper-clad laminates, which cannot fully meet the needs of advanced PCB packaging technology.

### SUMMARY

To overcome the problems facing prior arts, particularly one or more of the above-mentioned technical problems of conventional materials, it is a primary object of the present disclosure to provide a resin composition and an article made therefrom which may overcome at least one of the above-mentioned technical problems.

To achieve the above-mentioned object, the present disclosure provides a resin composition, comprising: (A) 100 parts by weight of a copolymer, the copolymer having a structural unit formed by a monomer of Formula (1) and a structural unit formed by a monomer of Formula (2), and the content of the structural unit formed by the monomer of Formula (2) in the copolymer is 55 wt % to 90 wt %; and (B) 1 part by weight to 15 parts by weight of a compound of Formula (3);

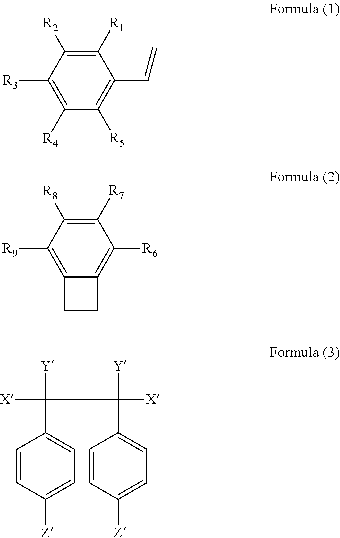

in Formula (1), R₁ to R₅ are each independently selected from a hydrogen atom, a C1 to C3 alkyl group, a C2 to C3 alkenyl group, a phenyl group, a phenyl group substituted by a C1 to C3 alkyl group, a phenyl group substituted by a C2 to C3 alkenyl group and a C2 to C3 alkenyl phenyl C1 to C3 alkylene group;
in Formula (2), R₆ to R₉ are each independently selected from a hydrogen atom, a C1 to C3 alkyl group and a C2 to C3 alkenyl group, and at least one of R₆ to R₉ is a C2 to C3 alkenyl group;
in Formula (3), each X′, Y′ and Z′ independently represent a hydrogen atom, a C1 to C4 alkyl group, a phenyl group, or an unsaturated C═C double bond-containing group.

For example, in one embodiment, the monomer of Formula (1) comprises a monomer of Formula (1-1), a monomer of Formula (1-2), a monomer of Formula (1-3), a monomer of Formula (1-4) or a combination thereof, and the monomer of Formula (2) comprises a monomer of Formula (2-1),

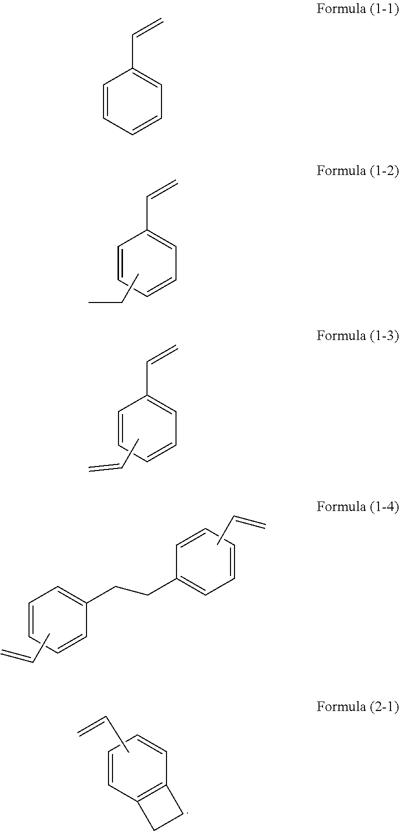

For example, in one embodiment, the copolymer comprises any one of a copolymer of Formula (4) to a copolymer of Formula (19) below or a combination thereof:

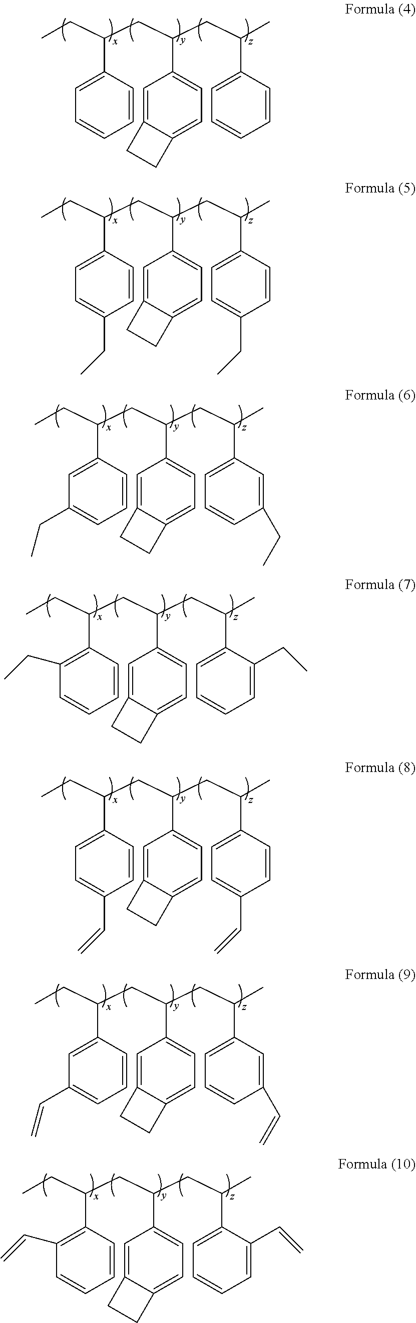

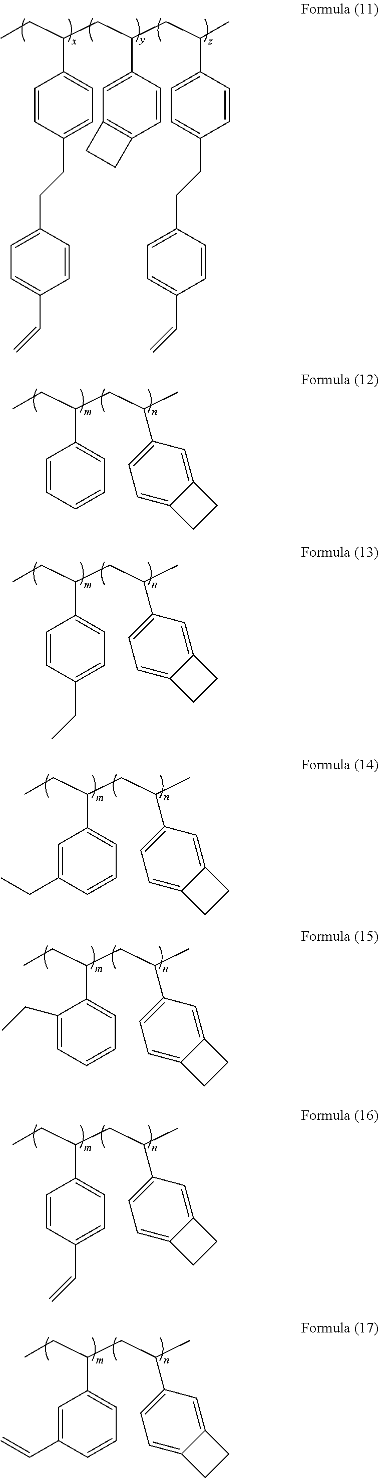

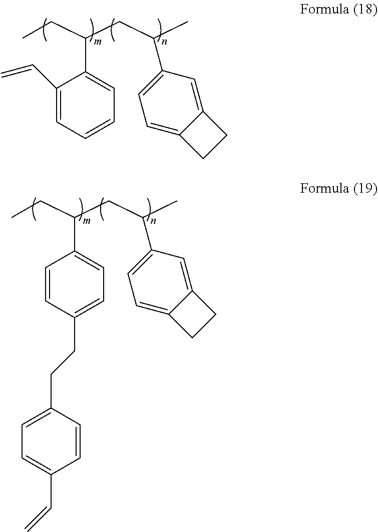

wherein m, n, x, y and z are each independently a positive integer, 25≤m≤44, 12≤n≤70, 2≤x+z≤44, and 12≤y≤70.

For example, in one embodiment, the copolymer comprises a block copolymer, a random copolymer or a combination thereof.

For example, in one embodiment, the compound of Formula (3) has at least one unsaturated C═C double bond-containing group.

For example, in one embodiment, in Formula (3), at least one of X′, Y′ and Z′ represents a vinyl group, a vinylbenzyl group, a vinylphenyl group, an allyl group or a (meth)acryloyloxy group.

For example, in one embodiment, the compound of Formula (3) comprises any one of a compound of Formula (3-1) to a compound of Formula (3-6) or a combination thereof:

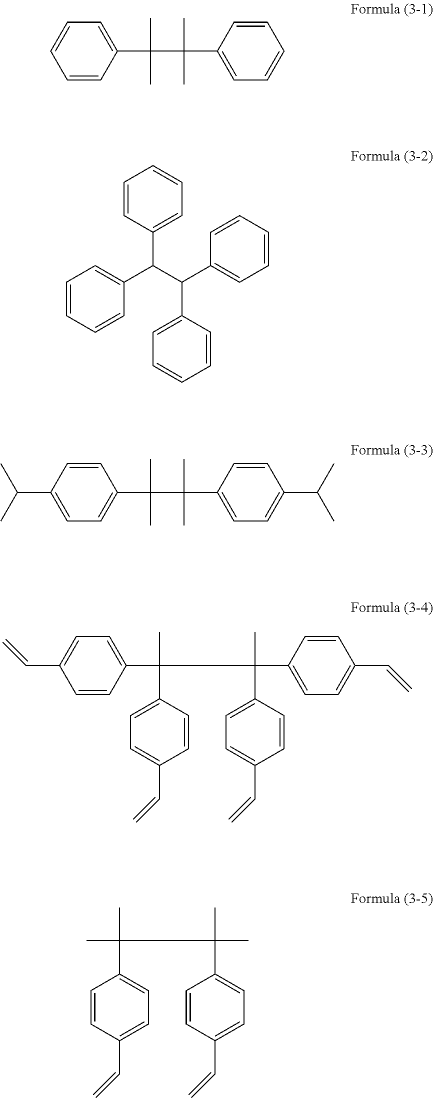

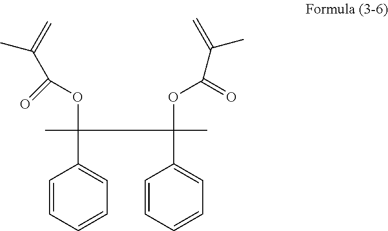 [SMILES: C=C(C)C(=O)OC(C)(c1ccccc1)C(C)(OC(=O)C(=C)C)c1ccccc1]

For example, in one embodiment, the resin composition further comprises an unsaturated C═C double bond-containing crosslinking agent, the unsaturated C═C double bond-containing crosslinking agent being selected from any one of bis(vinylphenyl)ethane, divinylbenzene, divinylnaphthalene, divinylbiphenyl, triallyl isocyanurate, triallyl cyanurate, vinylbenzocyclobutene, bis(vinylbenzyl)ether, trivinyl cyclohexane, diallyl bisphenol A, acrylate with two or more functional groups, butadiene, decadiene and octadiene or a combination thereof.

For example, in one embodiment, the resin composition further comprises any one of a polyolefin different from the copolymer, an unsaturated C═C double bond-containing polyphenylene ether resin, a benzoxazine resin, an epoxy resin, a polyester resin, a phenol resin, an amine curing agent, a polyamide, a polyimide, a styrene maleic anhydride, a maleimide resin, a cyanate ester or a combination thereof.

For example, in one embodiment, the resin composition further comprises an inorganic filler, a flame retardant, a curing accelerator different from the compound of Formula (3), a polymerization inhibitor, a solvent, a silane coupling agent, a coloring agent, a toughening agent or a combination thereof.

To achieve the above-mentioned objects, the present disclosure further provides an article made from the aforesaid resin composition, including a prepreg, a resin film, a laminate or a printed circuit board.

For example, in one embodiment, the article described above has at least one, more or all of the following properties:
a glass transition temperature as measured by reference to IPC-TM-650 2.4.24.4 of greater than or equal to 290° C.;
a storage modulus decay rate as measured and calculated by reference to IPC-TM-650 2.4.24.4 of less than or equal to 16%;
a reflow warpage magnitude as measured by reference to JESD22-B112A of less than or equal to 14 μm;
a percent of thermal expansion in Z-axis as measured by reference to IPC-TM-650 2.4.24.5 of less than or equal to 1.2%;
absence of branch-like pattern under visual inspection of the laminate appearance; and a dissipation factor as measured by reference to JIS C2565 at 10 GHz of less than or equal to 0.00086.

### DESCRIPTION OF THE EMBODIMENTS

To enable those skilled in the art to further appreciate the features and effects of the present disclosure, words and terms contained in the specification and appended claims are described and defined. Unless otherwise defined, all technical and scientific terms used herein have the same meaning as commonly understood by those of ordinary skill in the art to which this disclosure pertains. In the case of conflict, the present document and definitions contained herein will control.

While some theories or mechanisms may be proposed herein, the present disclosure is not bound by any theories or mechanisms described regardless of whether they are right or wrong, as long as the embodiments can be implemented according to the present disclosure.

As used herein, “a,” “an” or any similar expression is employed to describe components and features of the present disclosure. This is done merely for convenience and to give a general sense of the scope of the present disclosure. Accordingly, this description should be read to include one or at least one and the singular also includes the plural unless it is obvious to mean otherwise.

As used herein, the term “encompasses,” “encompassing,” “comprises,” “comprising,” “includes,” “including,” “has,” “having” or any other variant thereof is construed as an open-ended transitional phrase intended to cover a non-exclusive inclusion. For example, a composition comprising a list of elements or an article made therefrom encompasses any one or any type of the listed elements and is not necessarily limited to only those elements listed herein, but may also include other elements not expressly listed or inherent to such composition or article. Further, unless expressly stated to the contrary, the term “or” refers to an inclusive or and not to an exclusive or. For example, a condition “A or B” is satisfied by any one of the following: A is true (or present) and B is false (or not present), A is false (or not present) and B is true (or present), and both A and B are true (or present). In addition, whenever open-ended transitional phrases are used, such as “encompasses,” “encompassing,” “comprises,” “comprising,” “includes,” “including,” “has,” “having” or any other variant thereof, it is understood that close-ended transitional phrases such as “consisting of,” “composed by” and “remainder being” and partially open-ended transitional phrases such as “consisting essentially of,” “primarily consisting of,” “mainly consisting of,” “primarily containing,” “composed essentially of,” “essentially having,” etc. are also disclosed and included.

As used herein, “or a combination thereof” means “or any combination thereof” encompasses any combination of two or more of the listed elements, and “any” means “any one”, vice versa. For example, “a composition or an article made therefrom includes A, B, C or a combination thereof” is construed to encompass the following situations: A is true (or present), and B and C are false (or not present); B is true (or present), and A and C are false (or not present); C is true (or present), and A and B are false (or not present); A and B are true (or present), and C is false (or not present); A and C are true (or present), and B is false (or not present); B and C are true (or present), and A is false (or not present); A and B and C are all true (or present), and other elements not expressly listed but inherent to such composition or article.

As used herein, the term “and” or any other variant thereof is used to connect parallel sentence components, and there is no distinction between the front and rear components. The meaning of the parallel sentence components does not change in the grammatical sense after the position is exchanged.

In this disclosure, features and conditions such as values, numbers, contents, amounts or concentrations are presented as a numerical range or a percentage range merely for convenience and brevity. Therefore, a numerical range or a percentage range should be interpreted as encompassing and specifically disclosing all possible subranges and individual numerals or values therein, including integers and fractions, particularly all integers therein. For example, a range of “1.0 to 8.0” or “between 1.0 and 8.0” should be understood as explicitly disclosing all subranges such as 1.0 to 8.0, 1.0 to 7.0, 2.0 to 8.0, 2.0 to 6.0, 3.0 to 6.0, 4.0 to 8.0, 3.0 to 8.0 and so on and encompassing the endpoint values, particularly subranges defined by integers, as well as disclosing all individual values in the range such as 1.0, 2.0, 3.0, 4.0, 5.0, 6.0, 7.0 and 8.0. Unless otherwise defined, the aforesaid interpretation rule should be applied throughout the present disclosure regardless of broadness of the scope.

Whenever amount, concentration or other numeral or parameter is expressed as a range, a preferred range or a series of upper and lower limits, it is understood that all ranges defined by any pair of the upper limit or preferred value and the lower limit or preferred value are specifically disclosed, regardless whether these ranges are explicitly described or not. In addition, unless otherwise defined, whenever a range is mentioned, the range should be interpreted as inclusive of the endpoints and every integers and fractions in the range.

Given the intended purposes and advantages of this disclosure are achieved, numerals or figures have the precision of their significant digits. For example, 40.0 should be understood as covering a range of 39.50 to 40.49.

As used herein, a Markush group or a list of items is used to describe examples or embodiments of the present disclosure. A skilled artisan will appreciate that all subgroups of members or items and individual members or items of the Markush group or list can also be used to describe the present disclosure. For example, when X is described as being “selected from a group consisting of X1, X2 and X3,” it is intended to disclose the situations of X is X1 and X is X1 and/or X2 and/or X3. In addition, when a Markush group or a list of items is used to describe examples or embodiments of the present disclosure, a skilled artisan will understand that any subgroup or any combination of the members or items in the Markush group or list may also be used to describe the present disclosure. Therefore, for example, when X is described as being “selected from a group consisting of X1, X2 and X3” and Y is described as being “selected from a group consisting of Y1, Y2 and Y3,” the disclosure includes any combination of X is X1 and/or X2 and/or X3 and Y is Y1 and/or Y2 and/or Y3.

Unless otherwise specified, according to the present disclosure, a compound refers to a chemical substance formed by two or more elements bonded with chemical bonds and may comprise a small molecule compound and a polymer compound, but not limited thereto. Any compound disclosed herein is interpreted to not only include a single chemical substance but also include a class of chemical substances having the same kind of components or having the same property.

Unless otherwise specified, according to the present disclosure, a polymer refers to the product formed by monomer(s) via polymerization and usually comprises multiple aggregates of polymers respectively formed by multiple repeated simple structure units by covalent bonds; the monomer refers to the compound forming the polymer. A polymer may comprise a homopolymer, a copolymer, a prepolymer, etc., but not limited thereto. A homopolymer refers to the polymer formed by the polymerization of one monomer. A copolymer refers to the polymer formed by the polymerization of two or more types of monomers. Copolymers comprise: random copolymers, such as a structure of -AABABBBAAABBA-; alternating copolymers, such as a structure of -ABABABAB-; graft copolymers, such as a structure of -AA(A-BBBB)AA(A-BBBB)AAA-; and block copolymers, such as a structure of -AAAAA-BBBBBB-AAAAA-. For example, a styrene-butadiene copolymer disclosed herein is interpreted as comprising a styrene-butadiene random copolymer, a styrene-butadiene alternating copolymer, a styrene-butadiene graft copolymer or a styrene-butadiene block copolymer. A prepolymer refers to a polymer having a lower molecular weight between the molecular weight of monomer and the molecular weight of final polymer, and a prepolymer contains a reactive functional group capable of participating further polymerization to obtain the final polymer product which has been fully crosslinked or cured. The term “polymer” includes but is not limited to an oligomer. An oligomer refers to a polymer with 2 to 20, typically 2 to 5, repeating units.

To those of ordinary skill in the art to which this disclosure pertains, a resin composition containing an additive and three compounds (e.g., A, B and C), a total of four components, is different from a resin composition containing the additive and a prepolymer formed by the three compounds (e.g., A, B and C), a total of two components, as they are completely different from each other in the aspects of preparation method, physical or chemical properties of the resin composition and properties of an article or product made therefrom. For example, the former involves mixing A, B, C and the additive to form the resin composition; in contrast, the latter involves first subjecting a mixture comprising A, B and C to a prepolymerization reaction at proper conditions to form a prepolymer and then mixing the prepolymer with the additive to form the resin composition. For example, to those of ordinary skill in the art to which this disclosure pertains, the two resin compositions have completely different compositions; in addition, because the prepolymer formed by A, B and C functions completely different from A, B and C individually or collectively in the resin composition, the two resin compositions should be construed as completely different chemical substances and have completely different chemical statuses. For example, to those of ordinary skill in the art to which this disclosure pertains, because the two resin compositions are completely different chemical substances, articles made therefrom will not have the same properties. For example, to a resin composition containing a crosslinking agent and a prepolymer formed by A, B and C, since A, B and C have been partially reacted or converted during the prepolymerization reaction to form the prepolymer, during the process of heating to semi-cure the resin composition at a high temperature condition, a partial crosslinking reaction occurs between the prepolymer and the crosslinking agent but not between A, B and C individually and the crosslinking agent. As such, articles made from the two resin compositions will be completely different and have completely different properties.

Unless otherwise specified, the term “resin” of the present disclosure is a widely used common name of a synthetic polymer and is construed as comprising monomer and its combination, polymer and its combination or a combination of monomer and its polymer, but not limited thereto.

Unless otherwise specified, according to the present disclosure, a modification comprises a product derived from a resin with its reactive functional group modified, a product derived from a prepolymerization reaction of a resin and other resins, a product derived from a crosslinking reaction of a resin and other resins, a product derived from copolymerizing a resin and other resins, etc.

The unsaturated bond described herein, unless otherwise specified, refers to a reactive unsaturated bond, such as but not limited to an unsaturated double bond with the potential of being crosslinked with other functional groups, such as an unsaturated C═C double bond with the potential of being crosslinked with other functional groups, but not limited thereto.

The unsaturated C═C double bond as used herein preferably comprises, but not limited to, a vinyl group, a vinylbenzyl group, a vinylphenyl group, a (meth)acryloyloxy group, an allyl group or a combination thereof. The term “vinyl group” is construed as comprising a vinyl group and a vinylene group, and the term “(meth)acryloyloxy group” is construed as comprising an acryloyloxy group and a methacryloyloxy group.

Unless otherwise specified, the alkyl group, the alkenyl group and the monomer described herein are construed to encompass various isomers thereof. For example, a propyl group is construed to encompass n-propyl and iso-propyl.

Unless otherwise specified, as used herein, part(s) by weight represents weight part(s) in any weight unit in the resin composition, such as but not limited to kilogram, gram, pound and so on. For example, 100 parts by weight of the copolymer may represent 100 kilograms of the copolymer or 100 pounds of the copolymer.

Unless otherwise specified, in the present disclosure, wt % represents weight (or mass) percentage.

It should be understood that all features disclosed herein may be combined in any way to constitute the technical solution of the present disclosure, as long as there is no conflict present in the combination of these features.

Examples and embodiments are described in detail below. It will be understood that these examples and embodiments are exemplary only and are not intended to limit the scope and use of the present disclosure. Unless otherwise specified, processes, reagents and conditions described in the examples are those known in the art.

As described above, the present disclosure provides a resin composition, comprising the following components:
(A) 100 parts by weight of a copolymer, the copolymer having a structural unit formed by a monomer of Formula (1) and a structural unit formed by a monomer of Formula (2), and the content of the structural unit formed by the monomer of Formula (2) in the copolymer is 55 wt % to 90 wt %; and
(B) 1 part by weight to 15 parts by weight of a compound of Formula (3);

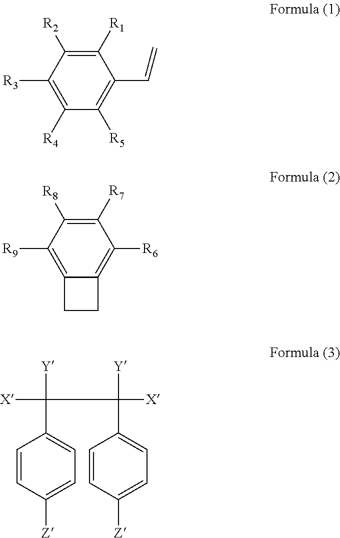

in Formula (1), R₁ to R₅ are each independently selected from hydrogen atom, C1 to C3 alkyl group (e.g., methyl, ethyl or propyl), C2 to C3 alkenyl group (e.g., vinyl or allyl), phenyl group, phenyl group substituted by C1 to C3 alkyl group (e.g., ethylphenyl), phenyl group substituted by C2 to C3 alkenyl group (e.g., vinylphenyl) and C2 to C3 alkenyl phenyl C1 to C3 alkylene (e.g., vinylphenyl ethylene);
in Formula (2), R₆ to R₉ are each independently selected from hydrogen atom, C1 to C3 alkyl group (e.g., methyl, ethyl or propyl) and C2 to C3 alkenyl group (e.g., vinyl or allyl), and at least one of R₆ to R₉ is C2 to C3 alkenyl group (e.g., vinyl or allyl); in Formula (3), each X′, Y′ and Z′ independently represent a hydrogen atom, a C1 to C4 alkyl group (e.g., methyl, ethyl, propyl or butyl), a phenyl group or an unsaturated C═C double bond-containing group (e.g., vinyl, vinylbenzyl, (meth)acryloyloxy, allyl, vinylphenyl or a combination thereof).

According to the present disclosure, the copolymer may be a copolymer having a structural unit formed by a monomer of Formula (1) and a structural unit formed by a monomer of Formula (2) or a mixture of two or more structurally different copolymers both having a structural unit formed by a monomer of Formula (1) and a structural unit formed by a monomer of Formula (2).

For example, in one embodiment, the monomer of Formula (1) comprises any one of a monomer of Formula (1-1), a monomer of Formula (1-2), a monomer of Formula (1-3), a monomer of Formula (1-4) or a combination thereof, and the monomer of Formula (2) comprises a monomer of Formula (2-1),

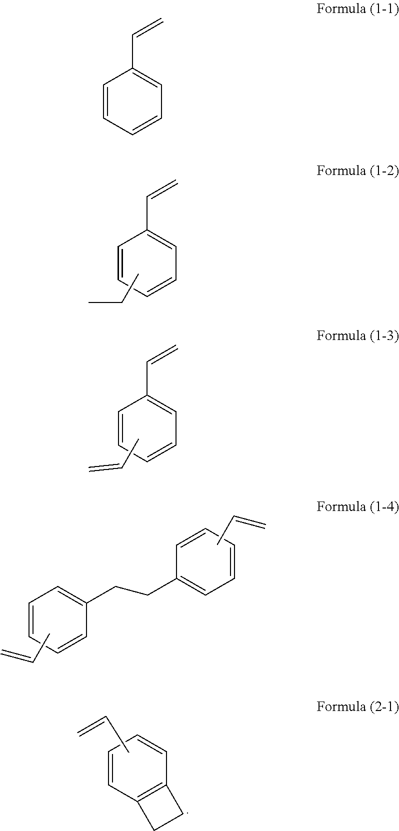

For example, in one embodiment, the copolymer is preferably a random copolymer or a block copolymer, more preferably a block copolymer.

For example, in one embodiment, the copolymer has a number average molecular weight (Mn) of: 1000≤Mn≤30000. Preferably, the copolymer has a number average molecular weight (Mn) of: 1500≤Mn≤20000.

For example, in one embodiment, the copolymer comprises any one of a copolymer of Formula (4) to a copolymer of Formula (19) below or a combination thereof:

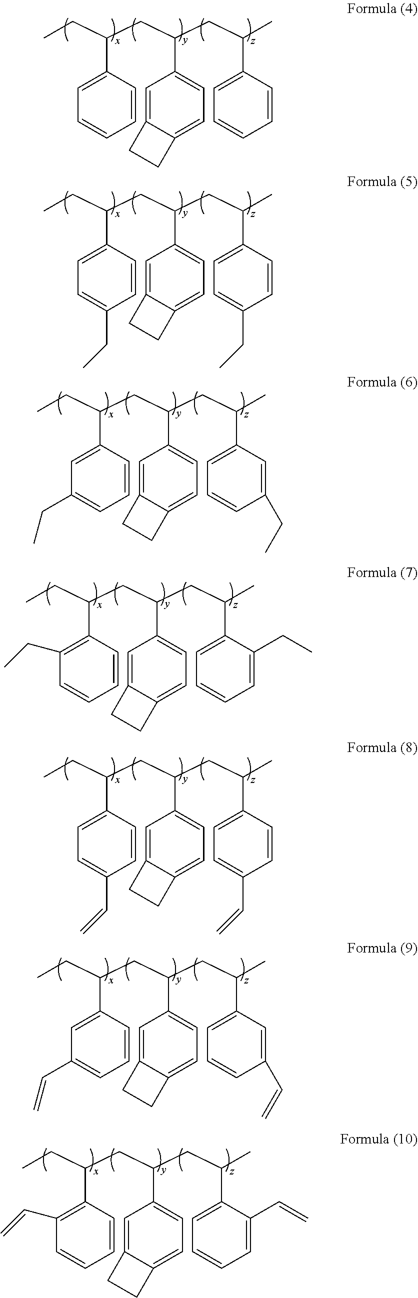

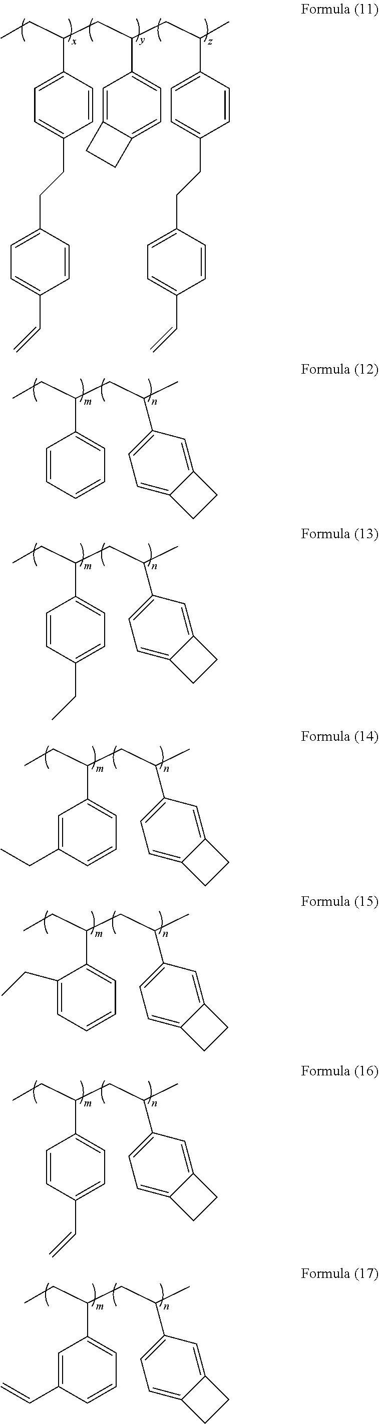

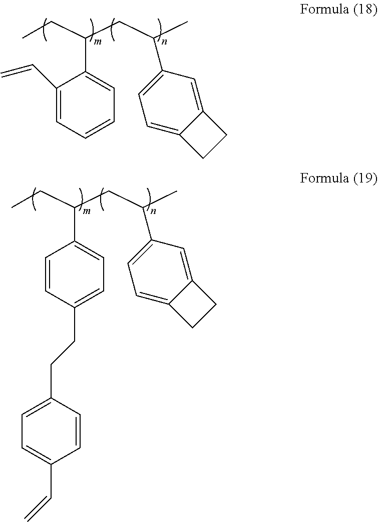

In Formula (4) to Formula (19), m, n, x, y and z are each independently a positive integer and conform to the following relationship: 2≤m≤44, 12≤n≤70, 2≤x+z≤44, and 12≤y≤70. For example, m=2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43 or 44; n=12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69 or 70; x+z=2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43 or 44; y=12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69 or 70. In addition, in Formula (4) to Formula (19), the content of the structural unit formed by the monomer of Formula (2) is 55 wt % to 90 wt %.

Among the above Formula (4) to Formula (19), Formula (4) to Formula (11) represent triblock copolymers, and the structural units are sequentially bonded to each other. For example, Formula (4) represents “x” structural units formed by monomers of Formula (1) (represented by a), “y” structural units formed by monomers of Formula (2) (represented by b) and “z” structural units formed by monomers of Formula (1) (represented by a) bonded in sequence. For example, when x is 2, y is 12, and z is 3 in Formula (4), the structural units are bonded to each other as follows: -aa-bbbbbbbbbbbb-aaa-. Formula (12) to Formula (19) represent random copolymers, with randomly bonding between each structural unit. This structural formula is used only for convenience of expression. For example, Formula (12) represents the randomly bonding between “m” structural units formed by monomers of Formula (1) (represented by a) and “n” structural units formed by monomers of Formula (2) (represented by b). For example, when m is 9 and n is 12 in Formula (12), the structural units are connected to each other in an unordered manner, such as but not limited to the following structure: -aababbbaaabbbbabbaabb-.

For example, in one embodiment, the copolymer comprises any block copolymers of Formula (4) to Formula (11), any random copolymers of Formula (12) to Formula (19) or a combination thereof. Preferably, the copolymer comprises any block copolymers of Formula (4) to Formula (11) or a combination thereof. For example, in one embodiment, an article made from any one of the copolymers represented by Formula (4) to Formula (19) or a combination thereof and the compound represented by Formula (3) has not only higher glass transition temperature and better laminate appearance, but also lower percent of thermal expansion in Z-axis, a smaller reflow warpage magnitude, lower storage modulus decay rate and lower dissipation factor. Furthermore, in one embodiment, when the copolymer is preferably any one of the block copolymers represented by Formula (4) to Formula (11) or a combination thereof, the above properties are significantly improved, especially with much lower storage modulus decay rate, much lower percent of thermal expansion in Z-axis and a much smaller reflow warpage magnitude.

The copolymer described herein which contains a structural unit formed by a monomer of Formula (1) and a structural unit formed by a monomer of Formula (2) may be prepared by various methods known by those having ordinary skilled in the art. For example, the copolymer may be prepared by the following processes:

1. The copolymer containing a structural unit formed by a monomer of Formula (1) and a structural unit formed by a monomer of Formula (2) is a block copolymer.

At 0° C. to 40° C., under the condition of an inert atmosphere, a solvent and an anionic initiator were added into a reaction vessel and then stirred rapidly. First, “a” gram of the first monomer of Formula (1) was added and reacted for 4 to 18 hours, then “b” gram of monomer of Formula (2) was added and continued to react for 4 to 18 hours, and finally “c” gram of the second monomer of Formula (1) was added and continued to react for 4 to 18 hours to obtain the block copolymer. The first monomer of Formula (1) and the second monomer of Formula (1) may be the same or different, and a, b and c satisfy the following relationship: (b/(a+b+c))×100%=55% to 90%.

The solvent in the above steps may be, such as but not limited to, a polar solvent (e.g., tetrahydrofuran) or a non-polar solvent (e.g., cyclohexane), preferably tetrahydrofuran.

The anionic initiator in the above steps may be, such as but not limited to, n-butyllithium or tert-butyllithium, preferably n-butyllithium.

The inert atmosphere in the above steps may be, such as but not limited to, argon atmosphere or nitrogen atmosphere, preferably argon atmosphere.

2. The copolymer containing a structural unit formed by a monomer of Formula (1) and a structural unit formed by a monomer of Formula (2) is a random copolymer.

Under the condition of 20° C. to 70° C., a solvent and a mixture of the monomer of Formula (1) and the monomer of Formula (2) were added into a reaction vessel (wherein the mass content of the monomer of Formula (2) in the mixture is 55 wt % to 90 wt %, and the total molar amount of the mixture is “d” mole), and the reaction was stirred, mixed well, and then added with a cationic initiator (the mole amount is “e” mole) to react for 4 to 72 hours to obtain the random copolymer having a content of the structural unit formed by the monomer of Formula (2) of 55 wt % to 90 wt %. “d” and “e” satisfy the following relationship: (e/d)×100%=0.5% to 25%.

The solvent in the above steps may be, such as but not limited to, n-propyl acetate, n-butyl acetate or tetrahydrofuran, preferably n-propyl acetate.

The cationic initiator in the above steps may be, such as but not limited to, boron trifluoride diethyl ether, boron trifluoride methyl ether or aluminum trichloride, preferably boron trifluoride diethyl ether.

Relative to 100 parts by weight of the copolymer, the resin composition of the present disclosure comprises 1 part by weight to 15 parts by weight of a compound of Formula (3).

For example, in one embodiment, the compound of Formula (3) has at least one unsaturated C═C double bond-containing group.

For example, in one embodiment, in Formula (3), at least one of X′, Y′ and Z′ represents a vinyl group, a styryl group, an allyl group or a (meth)acryloyloxy group.

For example, in one embodiment, the compound of Formula (3) comprises any one of a compound of Formula (3-1) to a compound of Formula (3-6) or a combination thereof:

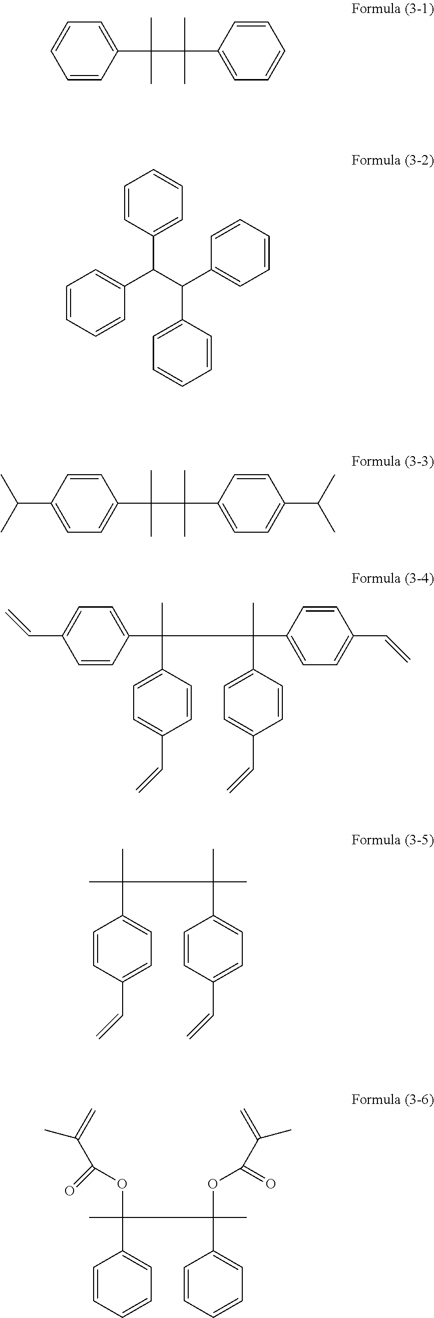

For example, in one embodiment, the resin composition of the present disclosure further comprises an unsaturated C═C double bond-containing crosslinking agent. For example, relative to 100 parts by weight of the copolymer, the resin composition of the present disclosure may comprise 1 part by weight to 50 parts by weight of an unsaturated C═C double bond-containing crosslinking agent, preferably 5 parts by weight to 35 parts by weight of an unsaturated C═C double bond-containing crosslinking agent.

The unsaturated C═C double bond-containing crosslinking agent suitable for the present disclosure refers to an unsaturated C═C double bond-containing small molecule compound containing two or more functional groups with a relative molecular mass of less than or equal to 1000, and the relative molecular mass thereof is preferably between 100 and 900, more preferably between 100 and 800. For example, the unsaturated C═C double bond-containing crosslinking agent is any one of bis(vinylphenyl)ethane (BVPE), divinylbenzene (DVB), divinylnaphthalene, divinylbiphenyl, triallyl isocyanurate (TAIC), triallyl cyanurate (TAC), vinylbenzocyclobutene (VBCB), bis(vinylbenzyl)ether (BVBE), trivinyl cyclohexane (TVCH), diallyl bisphenol A (DABPA), acrylate with two or more functional groups, butadiene, decadiene, octadiene, or a combination thereof.

The acrylate with two or more functional groups includes various bifunctional acrylates, trifunctional acrylates or tetrafunctional or higher acrylates commonly known in the art, and can be purchased from Shin Nakamura Chemical Industry Co., Ltd., Kyoeisha Chemical Co., Ltd., Nippon Kayaku Co., Ltd. or Sartomer. Examples include but are not limited to any one of diallyl isophthalate (DAIP), dioxane glycol diacrylate, tricyclodecane dimethanol diacrylate, tricyclodecane dimethanol dimethacrylate or a combination thereof.

For example, in one embodiment, the resin composition of the present disclosure may further optionally comprise any one of a polyolefin different from the copolymer, an unsaturated C═C double bond-containing polyphenylene ether resin, a benzoxazine resin, an epoxy resin, a polyester resin, a phenol resin, an amine curing agent, a polyamide, a polyimide, a styrene maleic anhydride, a maleimide resin, a cyanate ester or a combination thereof.

For example, in one embodiment, the resin composition of the present disclosure further comprises a polyolefin different from the copolymer. For example, relative to 100 parts by weight of the copolymer, the resin composition of the present disclosure may comprise 1 part by weight to 500 parts by weight of a polyolefin different from the copolymer, preferably 5 parts by weight to 100 parts by weight of a polyolefin different from the copolymer.

For example, in one embodiment, the polyolefin different from the copolymer suitable for the present disclosure is not particularly limited and may be any one or more polyolefins different from the copolymer useful for making a prepreg, a resin film, a laminate, or a printed circuit board, such as any one or more commercial products, products prepared by the Applicant or a combination thereof. For example, the polyolefin different from the copolymer suitable for the present disclosure includes but is not limited to a diene polymer, a monoene polymer, a hydrogenated diene polymer or a combination thereof. The diene polymer refers to a polymer of the hydrocarbon compound containing two unsaturated C═C double bonds in the molecule, and the monoene polymer refers to a polymer of the hydrocarbon compound containing one unsaturated C═C double bond in the molecule. The polyolefin different from the copolymer suitable for the present disclosure comprises, such as but not limited to, any one of polybutadiene, polyisoprene, styrene-butadiene copolymer, styrene-isoprene copolymer, styrene-butadiene-divinylbenzene polymer, polybutadiene-styrene copolymer adducted with maleic anhydride, vinyl-polybutadiene-urethane polymer, polybutadiene adducted with maleic anhydride, polymethylstyrene, hydrogenated polybutadiene, hydrogenated polyisoprene, hydrogenated styrene-butadiene-divinylbenzene polymer, hydrogenated styrene-butadiene copolymer adducted with maleic anhydride, hydrogenated styrene-butadiene copolymer, hydrogenated styrene-isoprene copolymer, epoxy group-containing polybutadiene and polyfunctional vinyl aromatic copolymer, or a combination thereof.

For example, unless otherwise specified, the polyfunctional vinyl aromatic copolymer may include various polyfunctional vinyl aromatic copolymers disclosed in the US Patent Application Publication No. 20070129502A1, all of which are incorporated herein by reference in their entirety.

For example, in one embodiment, the resin composition of the present disclosure further comprises an unsaturated C═C double bond-containing polyphenylene ether resin. For example, relative to 100 parts by weight of the copolymer, the resin composition of the present disclosure may comprise 1 part by weight to 500 parts by weight of an unsaturated C═C double bond-containing polyphenylene ether resin, preferably 5 parts by weight to 100 parts by weight of an unsaturated C═C double bond-containing polyphenylene ether resin.

For example, in one embodiment, the unsaturated C═C double bond-containing polyphenylene ether resin suitable for the present disclosure is not particularly limited and may be any one or more unsaturated C═C double bond-containing polyphenylene ether resins useful for making a prepreg, a resin film, a laminate or a printed circuit board and may be any one or more commercial products, products prepared by the Applicant or a combination thereof, such as but not limited to any one of a vinylbenzyl group-containing polyphenylene ether resin, a (meth)acryloyloxy group-containing polyphenylene ether resin and a vinyl group-containing polyphenylene ether resin or a combination thereof.

The unsaturated C═C double bond-containing polyphenylene ether resin of the present disclosure has an unsaturated C═C double bond and a phenylene ether skeleton, wherein the unsaturated C═C double bond is a reactive group which may perform self-polymerization under heat and may also perform free radical polymerization with other components containing an unsaturated bond in the resin composition and finally result in crosslinking and curing. Preferably, the unsaturated C═C double bond-containing polyphenylene ether resin comprises an unsaturated C═C double bond-containing polyphenylene ether resin with 2,6-dimethyl substitution in its phenylene ether skeleton, wherein the methyl groups form steric hindrance to prevent the oxygen atom of the ether group from forming a hydrogen bond or Van der Waals force to absorb moisture.

For example, in one embodiment, the unsaturated C═C double bond-containing polyphenylene ether resin comprises, but not limited to, a vinylbenzyl group-containing polyphenylene ether resin with a number average molecular weight of about 1200 (such as OPE-2st 1200, available from Mitsubishi Gas Chemical Co., Inc.), a vinylbenzyl group-containing polyphenylene ether resin with a number average molecular weight of about 2200 (such as OPE-2st 2200, available from Mitsubishi Gas Chemical Co., Inc.), a vinylbenzyl group-containing polyphenylene ether resin with a number average molecular weight of about 2400 to 2800 (such as a vinylbenzyl group-containing bisphenol A polyphenylene ether resin), a (meth)acryloyloxy group-containing polyphenylene ether resin with a number average molecular weight of about 1900 to 2300 (such as SA9000, available from Sabic), a vinyl group-containing polyphenylene ether resin with a number average molecular weight of about 2200 to 3000, or a combination thereof. The vinyl group-containing polyphenylene ether resin may include various polyphenylene ether resins disclosed in the US Patent Application Publication No. 20160185904A1, all of which are incorporated herein by reference in their entirety. For example, in one embodiment, the vinylbenzyl group-containing polyphenylene ether resin comprises, but not limited to, a vinylbenzyl group-containing biphenyl polyphenylene ether resin, a vinylbenzyl group-containing bisphenol A polyphenylene ether resin or a combination thereof.

Unless otherwise specified, in the resin composition of the present disclosure, relative to 100 parts by weight of the copolymer, the amount of a benzoxazine resin, an epoxy resin, a polyester resin, a phenol resin, a polyamide, a polyimide, a styrene maleic anhydride, a maleimide resin or a cyanate ester is not particularly limited and may for example range from 1 part by weight to 100 parts by weight, such as but not limited to 1 part by weight, 10 parts by weight, 15 parts by weight, 20 parts by weight, 25 parts by weight, 50 parts by weight or 100 parts by weight. Relative to 100 parts by weight of the copolymer, the amount of an amine curing agent is also not particularly limited and may for example range from 1 to 15 parts by weight, such as but not limited to 1 part by weight, 4 parts by weight, 7.5 parts by weight, 12 parts by weight or 15 parts by weight.

For example, in one embodiment, the benzoxazine resin may be any benzoxazine resins known in the field to which this disclosure pertains. Examples include but are not limited to bisphenol A benzoxazine resin, bisphenol F benzoxazine resin, phenolphthalein benzoxazine resin, dicyclopentadiene benzoxazine resin, phosphorus-containing benzoxazine resin, diamino benzoxazine resin and phenyl group-modified, vinyl group-modified or allyl group-modified benzoxazine resin or a combination thereof. Commercially available products include LZ-8270 (phenolphthalein benzoxazine resin), LZ-8298 (phenolphthalein benzoxazine resin), LZ-8280 (bisphenol F benzoxazine resin) and LZ-8290 (bisphenol A benzoxazine resin) available from Huntsman, and KZH-5031 (vinyl group-modified benzoxazine resin) and KZH-5032 (phenyl group-modified benzoxazine resin) available from Kolon Industries Inc. The diamino benzoxazine resin may be diaminodiphenylmethane benzoxazine resin, diaminodiphenyl ether benzoxazine resin, diaminodiphenyl sulfone benzoxazine resin, diaminodiphenyl sulfide benzoxazine resin or a combination thereof, but not limited thereto.

For example, in one embodiment, the epoxy resin may be any epoxy resins known in the field to which this disclosure pertains. In terms of improving the thermal resistance of the resin composition, the epoxy resin may include, but not limited to, any one of bisphenol A epoxy resin, bisphenol F epoxy resin, bisphenol S epoxy resin, bisphenol AD epoxy resin, novolac epoxy resin, trifunctional epoxy resin, tetrafunctional epoxy resin, multifunctional novolac epoxy resin, dicyclopentadiene (DCPD) epoxy resin, phosphorus-containing epoxy resin, p-xylene epoxy resin, naphthalene epoxy resin (e.g., naphthol epoxy resin), benzofuran epoxy resin, isocyanate-modified epoxy resin, or a combination thereof. According to the present disclosure, for example, the novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin or o-cresol novolac epoxy resin. According to the present disclosure, for example, the phosphorus-containing epoxy resin may be DOPO (9,10-dihydro-9-oxa-10-phosphaphenanthrene-10-oxide) epoxy resin, DOPO-HQ epoxy resin or a combination thereof. The DOPO epoxy resin may be any one or more selected from DOPO-containing phenol novolac epoxy resin, DOPO-containing o-cresol novolac epoxy resin and DOPO-containing bisphenol-A novolac epoxy resin. The DOPO-HQ epoxy resin may be any one or more selected from DOPO-HQ-containing phenol novolac epoxy resin, DOPO-HQ-containing o-cresol novolac epoxy resin and DOPO-HQ-containing bisphenol-A novolac epoxy resin, but not limited thereto.

For example, in one embodiment, the polyester resin may be any polyester resins known in the field to which this disclosure pertains. Examples include but are not limited to a dicyclopentadiene-containing polyester resin and a naphthalene-containing polyester resin or a combination thereof. Examples include, but not limited to, HPC-8000 or HPC-8150 available from D.I.C. Corporation.

For example, in one embodiment, the phenol resin may be any phenol resins known in the field to which this disclosure pertains. Examples include but are not limited to novolac resin or phenoxy resin, wherein the novolac resin includes at least one of phenol novolac resin, o-cresol novolac resin, bisphenol A novolac resin, naphthol novolac resin, biphenyl novolac resin and dicyclopentadiene phenol resin or a combination thereof, but not limited thereto.

For example, in one embodiment, the amine curing agent may be any amine curing agents known in the field to which this disclosure pertains. Examples include but are not limited to any one or a combination of diamino diphenyl sulfone, diamino diphenyl methane, diamino diphenyl ether, diamino diphenyl sulfide and dicyandiamide.

For example, in one embodiment, the polyamide may be any polyamides known in the field to which this disclosure pertains. Examples include but are not limited to various commercially available polyamide resin products.

For example, in one embodiment, the polyimide may be any polyimides known in the field to which this disclosure pertains. Examples include but are not limited to various commercially available polyimide resin products.

For example, in one embodiment, the styrene maleic anhydride may be any styrene maleic anhydrides known in the field to which this disclosure pertains, wherein the molar ratio of styrene (St) to maleic anhydride (MA) may be 1/1, 2/1, 3/1, 4/1, 6/1, 8/1 or 12/1. Examples include but are not limited to styrene maleic anhydride copolymers such as SMA-1000, SMA-2000, SMA-3000, EF-30, EF-40, EF-60 and EF-80 available from Cray Valley, or styrene maleic anhydride copolymers such as C400, C500, C700 and C900 available from Polyscope.

For example, in one embodiment, the maleimide resin may be any maleimide resins known in the field to which this disclosure pertains. Examples include but are not limited to: any one of 4,4′-diphenylmethane bismaleimide, polyphenylmethane maleimide, bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-xylylmaleimide, N-2,6-xylylmaleimide, N-phenylmaleimide, vinyl benzyl maleimide (VBM), maleimide containing biphenyl structure, maleimide resin containing aliphatic structure with 10 to 50 carbon atoms, maleimide containing indane structure, maleimide containing isopropyl and m-arylene structure, or a combination thereof. These components should be construed as including their modifications, including but not limited to diallyl compound-modified maleimide resin, diamine-modified maleimide resin, multi-functional amine-modified maleimide resin, acidic phenol compound-modified maleimide resin, cyanate-modified maleimide resin or a combination thereof.

For example, the maleimide resin includes but is not limited to products such as BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000, and BMI-7000H available from Daiwakasei Industry, products such as BMI-70 and BMI-80 available from K.I Chemical Industry Co., Ltd., or products such as MIR-3000 and MIR-5000 available from Nippon Kayaku.

For example, the maleimide resin containing aliphatic structure with 10 to 50 carbon atoms, also known as imide-extended maleimide resin, may include various imide-extended maleimide resins disclosed in the TW Patent Application Publication No. 200508284A, all of which are incorporated herein by reference in their entirety. The maleimide resin containing aliphatic structure with 10 to 50 carbon atoms suitable for the present disclosure may include, but not limited to, products such as BMI-689, BMI-1400, BMI-1500, BMI-1700, BMI-2500, BMI-3000, BMI-5000 and BMI-6000 available from Designer Molecules Inc.

According to the present disclosure, for example, in one embodiment, the cyanate-modified maleimide resin (a.k.a. maleimide triazine resin) may be any maleimide triazine resins known in the field to which this disclosure pertains. Examples include but are not limited to: maleimide triazine resin obtained by polymerizing maleimide resin and bisphenol A cyanate ester resin, maleimide triazine resin obtained by polymerizing maleimide resin and bisphenol F cyanate ester resin, maleimide triazine resin obtained by polymerizing maleimide resin and phenol novolac cyanate ester resin, and maleimide triazine resin obtained by polymerizing maleimide resin and dicyclopentadiene-containing cyanate ester resin. In one embodiment, the maleimide triazine resin can be obtained by polymerizing the maleimide resin and the cyanate ester resin in any molar ratio. For example, the molar ratio of maleimide resin to cyanate ester resin may be 1:1 to 1:10, such as but not limited to 1:1, 1:2, 1:4, 1:6, 1:8 or 1:10.

According to the present disclosure, for example, in one embodiment, the cyanate ester may be any cyanate ester resins known in the field to which this disclosure pertains, such as a compound having an Ar—O—C≡N structure, wherein Ar may be a substituted or unsubstituted aromatic group. In terms of improving the thermal resistance of the resin composition, examples include but are not limited to novolac cyanate ester resin, bisphenol A cyanate ester resin, bisphenol F cyanate ester resin, dicyclopentadiene-containing cyanate ester resin, naphthalene-containing cyanate ester resin, phenolphthalein cyanate ester resin, adamantane cyanate ester resin, fluorene cyanate ester resin or a combination thereof. The novolac cyanate ester resin may be bisphenol A novolac cyanate ester resin, bisphenol F novolac cyanate ester resin or a combination thereof. For example, the cyanate ester resin may be available under the product name Primaset PT-15, PT-30S, PT-60S, BA-200, BA-230S, BA-3000S, BTP-2500, BTP-6020S, DT-4000, DT-7000, ULL950S, HTL-300, CE-320, LVT-50, or LeCy sold by Lonza.

For example, in one embodiment, the resin composition further comprises any one of an inorganic filler, a flame retardant, a curing accelerator different from the compound of Formula (3), a polymerization inhibitor, a solvent, a silane coupling agent, a coloring agent, a toughening agent or a combination thereof.

According to the present disclosure, for example, in one embodiment, the inorganic filler may be any one or more inorganic fillers suitable for preparing a prepreg, a resin film, a laminate or a printed circuit board, examples thereof including but not limited to silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride, zirconium tungstate, petalite, calcined kaolin or a combination thereof. Moreover, the inorganic filler can be spherical (including solid sphere or hollow sphere), fibrous, plate-like, particulate, flake-like or whisker-like and can be optionally pretreated by a silane coupling agent. For example, in one embodiment, relative to 100 parts by weight of the copolymer, the resin composition of the present disclosure may further comprise 10 parts by weight to 300 parts by weight of an inorganic filler, preferably 50 parts by weight to 300 parts by weight of an inorganic filler, more preferably 80 parts by weight to 200 parts by weight of an inorganic filler, but not limited thereto.

According to the present disclosure, for example, in one embodiment, the flame retardant may be any one or more flame retardants suitable for preparing a prepreg, a resin film, a laminate or a printed circuit board, such as but not limited to a phosphorus-containing flame retardant or a bromine-containing flame retardant. The bromine-containing flame retardant preferably comprises decabromodiphenyl ethane, and the phosphorus-containing flame retardant preferably comprises: hydroquinone bis-(diphenyl phosphate), bisphenol A bis-(diphenylphosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenyl phosphate) (RDXP, such as commercially available PX-200, PX-201 and PX-202), ammonium polyphosphate, melamine polyphosphate, DPPO (diphenylphosphine oxide) and its derivatives (such as di-DPPO compounds) or resins, melamine cyanurate, tri-hydroxy ethyl isocyanurate, aluminium phosphinate (e.g., commercially available OP-930 and OP-935) or a combination thereof.

For example, in one embodiment, the flame retardant may be a flame retardant commercially available from Katayama Chemical Industries Co., Ltd., such as but not limited to V1, V2, V3, V4, V5, V7, S-2, S-4, E-4c, E-7c, E-8g, E-9g, E-10g, E-100, B-3, W-lo, W-2h, W-2o, W-3o, W-4o, OX-1, OX-2, OX-4, OX-6, OX-6+, OX-7, OX-7+, OX-13, BPE-1, BPE-3, HyP-2, API-9, CMPO, ME-20, C-1R, C-1S, C-3R, C-3S or C-11R. The flame retardant of the present disclosure may include one or more of the above flame retardants.

For example, unless otherwise specified, relative to 100 parts by weight of the copolymer, the resin composition of the present disclosure may further comprise 1 part by weight to 100 parts by weight of a flame retardant, preferably 1 part by weight to 50 parts by weight of a flame retardant, but not limited thereto.

According to the present disclosure, for example, in one embodiment, the curing accelerator different from the compound of Formula (3) may comprise a catalyst, such as a Lewis base or a Lewis acid. The Lewis base may comprise any one or more of imidazole, boron trifluoride-amine complex, ethyltriphenyl phosphonium chloride, 2-methylimidazole (2MI), 2-phenyl-1H-imidazole (2PZ), 2-ethyl-4-methylimidazole (2E4MZ), triphenylphosphine (TPP) and 4-dimethylaminopyridine (DMAP). The Lewis acid may comprise metal salt compounds, such as those of manganese, iron, cobalt, nickel, copper and zinc, such as zinc octanoate or cobalt octanoate. The curing accelerator also includes a curing initiator, such as a peroxide capable of producing free radicals. The curing initiator comprises but is not limited to: dicumyl peroxide (DCP), t-butyl peroxybenzoate, dibenzoyl peroxide (BPO), 2,5-dimethyl-2,5-di(t-butylperoxy)-3-hexyne (25B), bis(t-butylperoxyisopropyl)benzene or a combination thereof. For example, in one embodiment, relative to 100 parts by weight of the copolymer, the resin composition of the present disclosure may further comprise 0.001 part by weight to 5 parts by weight of a curing accelerator different from the compound of Formula (3), preferably 0.01 part by weight to 3.5 parts by weight of a curing accelerator different from the compound of Formula (3), more preferably 0.1 part by weight to 2.0 parts by weight of a curing accelerator different from the compound of Formula (3), but not limited thereto.

According to the present disclosure, for example, in one embodiment, the polymerization inhibitor may comprise, but not limited to, 1,1-diphenyl-2-picrylhydrazyl radical, methyl acrylonitrile, nitroxide-mediated radical, triphenylmethyl radical, metal ion radical, sulfur radical (such as including but not limited to dithioester), hydroquinone, 4-methoxyphenol, p-benzoquinone, phenothiazine, p-phenylnaphthylamine, 4-t-butylcatechol, methylene blue, 4,4′-butylidenebis(6-t-butyl-3-methylphenol) and 2,2′-methylenebis(4-ethyl-6-t-butylphenol) or a combination thereof. For example, the nitroxide-mediated radical may comprise, but not limited to, nitroxide radicals derived from cyclic hydroxylamines, such as 2,2,6,6-tetramethyl-1-oxo-piperidine, 2,2,6,6-substituted piperidine 1-oxyl free radical, 2,2,5,5-substituted pyrrolidine 1-oxyl free radical or the like. Preferred substitutes include alkyl groups with 4 or fewer carbon atoms, such as methyl group or ethyl group. Examples of the compound containing a nitroxide radical include but are not limited to 2,2,6,6-tetramethylpiperidine 1-oxyl free radical, 2,2,6,6-tetraethylpiperidine 1-oxyl free radical, 2,2,6,6-tetramethyl-4-oxo-piperidine 1-oxyl free radical, 2,2,5,5-tetramethylpyrrolidine 1-oxyl free radical, 1,1,3,3-tetramethyl-2-isoindoline oxygen radical, N,N-di-tert-butylamine oxygen free radical and so on. Nitroxide radicals may also be replaced by using stable radicals such as galvinoxyl radicals. The polymerization inhibitor suitable for the resin composition of the present disclosure may include products derived from the polymerization inhibitor with its hydrogen atom or group substituted by other atom or group. Examples include products derived from a polymerization inhibitor with its hydrogen atom substituted by an amino group, a hydroxyl group, a carbonyl group or the like. For example, in one embodiment, relative to 100 parts by weight of the copolymer, the resin composition of the present disclosure may further comprise 0.001 part by weight to 20 parts by weight of a polymerization inhibitor, preferably 0.001 part by weight to 10 parts by weight of a polymerization inhibitor, but not limited thereto.

According to the present disclosure, for example, in one embodiment, the solvent may be any solvents suitable for dissolving the resin composition of the present disclosure, including but not limited to: methanol, ethanol, ethylene glycol monomethyl ether, acetone, butanone (methyl ethyl ketone), methyl isobutyl ketone, cyclohexanone, N-methyl-pyrrolidone, toluene, xylene, methoxyethyl acetate, ethoxyethyl acetate, propoxyethyl acetate, ethyl acetate, dimethylformamide, dimethylacetamide, propylene glycol monomethyl ether acetate, or a mixture thereof. The amount of a solvent is added with the aim of fully dissolving the resin and achieving a specific total solid content of the resin composition. For example, in one embodiment, the amount of the solvent is added in order to adjust the total solid content of the resin composition to 50 wt % to 85 wt %, but not limited thereto.

According to the present disclosure, for example, in one embodiment, the silane coupling agent may comprise silane (such as but not limited to siloxane), which may be further categorized according to the functional groups into amino silane, epoxide silane, vinyl silane, hydroxyl silane, isocyanate silane, methacryloxy silane and acryloxy silane. For example, in one embodiment, relative to 100 parts by weight of the copolymer, the resin composition of the present disclosure may further comprise 0.001 part by weight to 20 parts by weight of a silane coupling agent, preferably 0.01 part by weight to 10 parts by weight of a silane coupling agent, but not limited thereto.

According to the present disclosure, for example, in one embodiment, the coloring agent may comprise but is not limited to dye or pigment. For example, in one embodiment, relative to 100 parts by weight of the copolymer, the resin composition of the present disclosure may further comprise 0.001 part by weight to 10 parts by weight of a coloring agent, preferably 0.01 part by weight to 5 parts by weight of a coloring agent, but not limited thereto.

According to the present disclosure, the main purpose of adding a toughening agent is to improve the toughness of the resin composition. For example, the toughening agent suitable for the present disclosure may comprise, but not limited to, carboxyl-terminated butadiene acrylonitrile rubber (CTBN rubber), core-shell rubber, ethylene propylene rubber or a combination thereof. For example, in one embodiment, relative to 100 parts by weight of the copolymer, the resin composition of the present disclosure may further comprise 1 part by weight to 20 parts by weight of a toughening agent, preferably 3 parts by weight to 10 parts by weight of a toughening agent, but not limited thereto.

The resin composition of various embodiments may be processed to make different articles, such as those suitable for use as components in electronic products, including but not limited to a prepreg, a resin film, a laminate or a printed circuit board.

For example, the resin composition of the disclosure can be used to make a prepreg, which comprises a reinforcement material and a layered structure disposed thereon. The layered structure is formed by heating the resin composition at a high temperature to the B-stage. Suitable baking temperature for making a prepreg may be for example 120° C. to 180° C., preferably 120° C. to 160° C. For example, the reinforcement material may be any one of a fiber material, woven fabric, and non-woven fabric, and the woven fabric preferably comprises fiberglass fabrics. The types of fiberglass fabrics are not particularly limited and may be any fiberglass fabric used for various printed circuit boards, such as E-glass fabric, D-glass fabric, S-glass fabric, T-glass fabric, L-glass fabric, Q-glass fabric or QL-glass fabric (glass fabric with hybrid structure made of Q-glass and L-glass); the fiber may comprise yarns and rovings, in spread form or standard form, and the shape of terminal face may be round or flat. Non-woven fabric preferably comprises liquid crystal polymer non-woven fabric, such as polyester non-woven fabric, polyurethane non-woven fabric and so on, but not limited thereto. Woven fabric may also comprise liquid crystal polymer woven fabric, such as polyester woven fabric, polyurethane woven fabric and so on, but not limited thereto. The reinforcement material may increase the mechanical strength of the prepreg. In one preferred embodiment, the reinforcement material can also be optionally pre-treated by a silane coupling agent. The prepreg may be further heated and cured to the C-stage to form an insulation layer.

For example, the resin composition of the disclosure can be used to make a resin film, which is prepared by heating and baking to semi-cure the resin composition. The resin composition may be selectively coated on a liquid crystal polymer film, a polytetrafluoroethylene film, a polyethylene terephthalate film (PET film), a polyimide film (PI film), a copper foil or a resin-coated copper, followed by heating and baking to semi-cure the resin composition to form the resin film.

For example, the resin composition described herein may be made into a laminate, which comprises at least two metal foils and at least one insulation layer disposed between the metal foils, wherein the insulation layer is made by curing the resin composition at high temperature and high pressure to the C-stage, a suitable curing temperature being for example between 190° C. and 220° C. and preferably between 200° C. and 210° C., a suitable curing time being 90 to 180 minutes and preferably 120 to 150 minutes, and a suitable lamination pressure may be for example between 300 psi and 550 psi and preferably between 400 psi and 500 psi. The insulation layer may be obtained by curing the aforesaid prepreg or resin film. The metal foil may contain copper, aluminum, nickel, platinum, silver, gold or alloy thereof, such as a copper foil. In a preferred embodiment, the laminate is a copper-clad laminate.

In one embodiment, the laminate may be further processed by trace formation processes to obtain a printed circuit board. In one embodiment of making the printed circuit board according to the present disclosure, a double-sided copper-clad laminate (such as product EM-827, available from Elite Material Co., Ltd.) with a thickness of 28 mil and having a 1-ounce (oz) HTE (high temperature elongation) copper foil may be used and subjected to drilling and then electroplating, so as to form electrical conduction between the top layer copper foil and the bottom layer copper foil. Then the top layer copper foil and the bottom layer copper foil are etched to form an inner layer circuit board. Then brown oxidation and roughening are performed on the inner layer circuit board to form uneven structures on the surface to increase roughness. Next, a vacuum lamination apparatus is used to laminate the assembly containing a copper foil, the prepreg, the inner layer circuit board, the prepreg and a copper foil stacked in said order by heating at 190° C. to 220° C. for 90 to 180 minutes to cure the insulation material of the prepregs. Next, black oxidation, drilling, copper plating and other known circuit board processes are performed on the outmost copper foils so as to obtain the printed circuit board.

For example, in one embodiment, the various articles disclosed herein made from the resin composition may preferably have any one, more or all of the following properties:
a glass transition temperature as measured by reference to IPC-TM-650 2.4.24.4 of greater than or equal to 290° C., such as between 290° C. and 358° C.; a storage modulus decay rate as measured and calculated by reference to IPC-TM-650 2.4.24.4 of less than or equal to 16%, such as between 6% and 16%;
a reflow warpage magnitude as measured by reference to JESD22-B112A of less than or equal to 14 μm, such as between 5 μm and 14 μm;
a percent of thermal expansion in Z-axis as measured by reference to IPC-TM-650 2.4.24.5 of less than or equal to 1.2%, such as between 0.6% and 1.2%;
a dissipation factor as measured by reference to JIS C2565 at 10 GHz of less than or equal to 0.00086, such as between 0.00070 and 0.00086; and absence of branch-like pattern under visual inspection of the laminate appearance.

Raw materials below were used to prepare the resin compositions of various Examples and Comparative Examples of the present disclosure according to the amount listed in Table 1 to Table 5 and further fabricated to prepare test samples.

Materials and reagents used in Examples and Comparative Examples disclosed herein are listed below:
Copolymers A1 to A11 and B1 to B4: prepared according to Synthesis Examples 1 to 12. The Copolymers A1 to A11 are the copolymers disclosed herein (having a structural unit formed by a monomer of Formula (1) and a structural unit formed by a monomer of Formula (2), and the content of the structural unit formed by the monomer of Formula (2) in the copolymer being 55 wt % to 90 wt %); for Copolymers B1 and B2, the content of the structural unit formed by the monomer of Formula (2) in the copolymer is not in a range of 55 wt % to 90 wt %; Copolymer B3 is a homopolymer of the monomer of Formula (2), and it is placed under the column of copolymer for the convenience of side-by-side comparison; and Copolymer B4 does not contain a structural unit formed by the monomer of Formula (2).
Compound of Formula (3-1): 2,3-dimethyl-2,3-diphenylbutane, available from Wuxi Zhufeng Fine Chemical Co., Ltd.
Compound of Formula (3-2): 1,1,2,2-tetraphenylethane, available from Wuxi Zhufeng Fine Chemical Co., Ltd.
Compound of Formula (3-3):
1-[2,3-dimethyl-3-(4-propan-2-ylphenyl)butan-2-yl]-4-propan-2-ylbenzene, available from Wuxi Zhufeng Fine Chemical Co., Ltd.
Compound of Formula (3-4): prepared by the Applicant, as described in detail below.
Compound of Formula (3-5): prepared by the Applicant, as described in detail below.
Compound of Formula (3-6): prepared by the Applicant, as described in detail below.
DCP: dicumyl peroxide, available from NOF Corporation.
25B: 2,5-dimethyl-2,5-di(t-butylperoxy)-3-hexyne, available from NOF Corporation.
2E4MZ: 2-ethyl-4-methylimidazole, available from Kingyorker Enterprise Co., Ltd.
B-3000: polybutadiene, available from Nippon Soda Co., Ltd.
Ricon 100: styrene-butadiene copolymer, available from Cray Valley.
SBS-A: styrene-butadiene-styrene triblock copolymer, available from Nippon Soda.
H-1051: hydrogenated butadiene-styrene copolymer, available from Asahi KASEI.
BVPE: bis(vinylphenyl)ethane, available from Linchuan Chemical Co., Ltd.
SC-2500 SVJ: spherical silica pre-treated by silane coupling agent, available from Admatechs.
Toluene: available from Sinopec Group. The amount of toluene is shown as “PA” in the Tables to indicate a “proper amount” to represent an amount of toluene used to achieve a 60% to 68% solid content (solid content, S/C=60% to 68%) of the whole resin composition.

### Synthesis Example 1: Preparation of St-VBCB-St Block Copolymer

Under the condition of 40° C., 1 L of dehydrated tetrahydrofuran (THF) was added into a Schlenk reaction flask, which was then vacuum-pumped in a liquid nitrogen environment and introduced with nitrogen, and the above operation was repeated three times; after that, the reaction was added with 1.64 g of n-butyllithium and stirred rapidly. Styrene (hereinafter abbreviated as St) was first added, 4-vinylbenzocyclobutene (hereinafter abbreviated as VBCB) was then added after 10 hours of reaction, and St was added after continuous reaction of 10 hours (the mass ratio of the three reagents is 22.5:55:22.5, a total of 50 ml). After continuing the reaction for 10 hours, a compound of Formula (4) with a VBCB content of 55 wt % was obtained, having a Mn of about 2002 to 2340, designated as A1.

Under the condition of 30° C., 1 L of dehydrated cyclohexane was added into a Schlenk reaction flask, which was then vacuum-pumped in a liquid nitrogen environment and introduced with nitrogen, and the above operation was repeated three times; after that, the reaction was added with 0.87 g of n-butyllithium and stirred rapidly. St was first added, VBCB was then added after 18 hours of reaction, and St was added after continuous reaction of 18 hours (the mass ratio of the three reagents is 12.5:75:12.5, a total of 50 ml). After continuing the reaction for 18 hours, a compound of Formula (4) with a VBCB content of 75 wt % was obtained, having a Mn of about 3692 to 4030, designated as A2.

Under the condition of 0° C. in iced water, 1 L of dehydrated THF was added into a Schlenk reaction flask, which was then vacuum-pumped in a liquid nitrogen environment and introduced with nitrogen, and the above operation was repeated three times; after that, the reaction was added with 0.42 g of tert-butyllithium and stirred rapidly. St was first added, VBCB was then added after 6 hours of reaction, and St was added after continuous reaction of 6 hours (the mass ratio of the three reagents is 5:90:5, a total of 50 ml). After continuing the reaction for 6 hours, a compound of Formula (4) with a VBCB content of 90 wt % was obtained, having a Mn of about 8242 to 8580, designated as A3.

### Synthesis Example 2: Preparation of Ethyl Vinylbenzene-VBCB-Ethyl Vinylbenzene Block Copolymer

Under the condition of 25° C., 1 L of dehydrated THF was added into a Schlenk reaction flask, which was then vacuum-pumped in a liquid nitrogen environment and introduced with nitrogen, and the above operation was repeated three times; after that, the reaction was added with 0.27 g of n-butyllithium and stirred rapidly. m-Ethyl vinylbenzene was first added, VBCB was then added after 12 hours of reaction, and m-ethyl vinylbenzene was added after continuous reaction of 12 hours (the mass ratio of the three reagents is 12.5:75:12.5, a total of 50 ml). After continuing the reaction for 12 hours, a compound of Formula (6) with a VBCB content of 75 wt % was obtained, having a Mn of about 13702 to 14092, designated as A4.

### Synthesis Example 3: Preparation of DVB-VBCB-DVB Block Copolymer

Under the condition of 25° C., 1 L of dehydrated THF was added into a Schlenk reaction flask, which was then vacuum-pumped in a liquid nitrogen environment and introduced with nitrogen, and the above operation was repeated three times; after that, the reaction was added with 0.054 g of n-butyllithium and stirred rapidly. o-Divinylbenzene (DVB) was first added, VBCB was then added after 4 hours of reaction, and o-DVB was added after continuous reaction of 4 hours (the mass ratio of the three reagents is 12.5:75:12.5, a total of 10 ml). After continuing the reaction for 4 hours, a compound of Formula (10) with a VBCB content of 75 wt % was obtained, having a Mn of about 13650 to 14040, designated as A5.

### Synthesis Example 4: Preparation of BVPE-VBCB-BVPE Block Copolymer

Under the condition of 25° C., 1 L of dehydrated THF was added into a Schlenk reaction flask, which was then vacuum-pumped in a liquid nitrogen environment and introduced with nitrogen, and the above operation was repeated three times; after that, the reaction was added with 0.052 g of n-butyllithium and stirred rapidly. p-Bis(vinylphenyl)ethane (BVPE) was first added, VBCB was then added after 4 hours of reaction, and BVPE was added after continuous reaction of 4 hours (the mass ratio of the three reagents is 5:90:5, a total of 10 ml). After continuing the reaction for 4 hours, a compound of Formula (11) with a VBCB content of 90 wt % was obtained, having a Mn of about 13286 to 13884, designated as A6.

### Synthesis Example 5: Preparation of St-VBCB Random Copolymer

21 g of n-propyl acetate and 50 g of a mixture of VBCB and St (wherein the mass proportion of VBCB is 90%) were added to a reaction flask, stirred evenly, and then added with 2.8 g of boron trifluoride diethyl ether, followed by heating to 40° C. and reacting for 72 hours to obtain a compound of Formula (12) with a VBCB content of 90 wt %, having a Mn of about 7800 to 9812, designated as A7.

50 g of n-butyl acetate and 50 g of a mixture of VBCB and St (wherein the mass proportion of VBCB is 55%) were added to a reaction flask, stirred evenly, and then added with 9.8 g of boron trifluoride methyl ether, followed by reacting at 20° C. for 36 hours to obtain a compound of Formula (12) with a VBCB content of 55 wt %, having a Mn of about 1864 to 3012, designated as A8.

### Synthesis Example 6: Preparation of Ethyl Vinylbenzene-VBCB Random Copolymer

70 g of tetrahydrofuran and 50 g of a mixture of VBCB and p-ethyl vinylbenzene (wherein the mass proportion of VBCB is 75%) were added to a reaction flask, stirred evenly, and then added with 9.2 g of aluminium trichloride, followed by heating to 70° C. and reacting for 4 hours to obtain a compound of Formula (13) with a VBCB content of 75 wt %, having a Mn of about 1987 to 4653, designated as A9.

### Synthesis Example 7: Preparation of DVB-VBCB Random Copolymer

23 g of n-propyl acetate and 10 g of a mixture of VBCB and m-divinylbenzene (m-DVB) (wherein the mass proportion of VBCB is 75%) were added to a reaction flask, stirred evenly, and then added with 0.44 g of boron trifluoride diethyl ether, followed by heating to 40° C. and reacting for 4 hours to obtain a compound of Formula (17) with a VBCB content of 75 wt %, having a Mn of about 8045 to 9638, designated as A10.

### Synthesis Example 8: Preparation of BVPE-VBCB Random Copolymer

20 g of n-propyl acetate and 10 g of a mixture of VBCB and BVPE (wherein the mass proportion of VBCB is 90%) were added to a reaction flask, stirred evenly, and then added with 0.42 g of boron trifluoride diethyl ether, followed by heating to 40° C. and reacting for 4 hours to obtain a compound of Formula (19) with a VBCB content of 90 wt %, having a Mn of about 9134 to 11065, designated as A11.

### Synthesis Example 9: Preparation of St-VBCB Random Copolymer (with a VBCB Content of 50 wt %)

50 g of n-propyl acetate and 50 g of a mixture of VBCB and St (wherein the mass proportion of VBCB is 50%) were added to a reaction flask, stirred evenly, and then added with 1.09 g of boron trifluoride diethyl ether, followed by heating to 40° C. and reacting for 72 hours to obtain a St-VBCB random copolymer (with a VBCB content of 50 wt %), designated as B1.

### Synthesis Example 10: Preparation of St-VBCB Random Copolymer (with a VBCB Content of 30 wt %)

50 g of n-propyl acetate and 50 g of a mixture of VBCB and St (wherein the mass proportion of VBCB is 30%) were added to a reaction flask, stirred evenly, and then added with 1.09 g of boron trifluoride diethyl ether, followed by heating to 40° C. and reacting for 72 hours to obtain a St-VBCB random copolymer (with a VBCB content of 30 wt %), designated as B2.

### Synthesis Example 11: Preparation of VBCB Homopolymer (with a VBCB Content of 100 wt %)

50 g of n-propyl acetate and 50 g of VBCB were added to a reaction flask, stirred evenly, and then added with 1.09 g of boron trifluoride diethyl ether, followed by heating to 40° C. and reacting for 48 hours to obtain a VBCB homopolymer (with a VBCB content of 100 wt %), designated as B3.

### Synthesis Example 12: Preparation of BCB-Modified DVB-St Copolymer (as Shown Below)

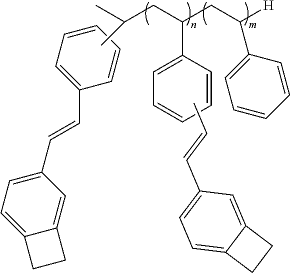

After a reactor was evacuated and introduced with nitrogen repeatedly for 3 times, 2.5 moles of 4-bromobenzocyclobutene, 7.5 moles of divinylbenzene, 0.0075 mole of palladium acetate, 0.03 mole of tri(o-methylphenyl)phosphine, 2.63 moles of triethylamine and 2 L of dry acetonitrile were added. The system was replaced with nitrogen again, followed by heating the water bath to 58° C. The reaction was completed after 48 hours, and a large amount of salt was precipitated after cooling to room temperature and then filtered with suction to remove the solid and palladium black. The filtrate was concentrated by rotary evaporation to remove the solvent, and then filtered with silica gel. The filtrate obtained by the suction filtration was distilled under reduced pressure at 80° C. to 90° C. to remove unreacted raw materials to obtain a brownish-yellow liquid, which was then purified by reduced pressure distillation successively at 90° C. and 150° C. to obtain a benzocyclobutene mono-substituted divinylbenzene monomer.

0.025 mole of the benzocyclobutene mono-substituted divinylbenzene monomer and 0.025 mole of styrene monomer were added to a single-necked bottle. The single-necked bottle was covered with a rubber stopper, which was then vacuum-pumped and introduced with nitrogen repeatedly for 3 times, followed by adding 22 ml of toluene by injection. The reaction was stirred at 100° C. for 10 hours, cooled to room temperature, and precipitated with methanol three times to obtain white powder, which is a BCB-modified DVB-St copolymer, designated as B4.

### Synthesis Example 13: Compound of Formula (3-4)

In a three-necked flask under nitrogen protection, 1 mol of 1,1′-bis(4-bromophenyl)ethane, 1.2 mol of vinylmagnesium bromide in a tetrahydrofuran solution and 0.05 mol of palladium dichloride were added in such order and refluxed for 24 hours. A saturated aqueous ammonium chloride solution was added to quench the reaction, which was then extracted with a dichloromethane solution. The organic phases were combined and evaporated to remove the solvent so as to obtain a crude product, which was separated by column chromatography to obtain 0.9 mol of 1,1′-bis(4-vinylphenyl)ethane.

In a three-necked flask, 0.8 mol of 1,1′-bis(4-vinylphenyl)ethane, 1.6 mol of N-bromosuccinimide, 0.05 mol of dibenzoyl peroxide and an appropriate amount of carbon tetrachloride were added in such order and refluxed for 12 hours. The reaction solution was washed three times with a sodium thiosulfate solution, and the solvent was evaporated to obtain a dry powder solid, which was recrystallized by acetone to obtain 1,1′-bis(4-vinylphenyl)-1-bromoethane.

In a reaction flask, 0.5 mol of 1,1′-bis(4-vinylphenyl)-1-bromoethane and 1 mol of silver-activated zinc powder were added in such order and reacted for 2 hours. After cooling to room temperature, saturated ammonium chloride was used to quench the reaction, which was filtered to remove unreacted zinc powder and separated by column chromatography to obtain 2,3-tetra(4-vinylphenyl)butane, designated as a compound of Formula (3-4), as shown below.

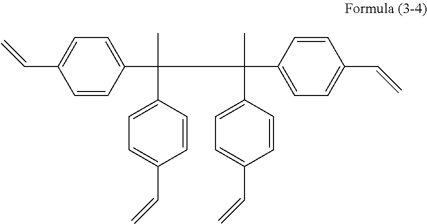 [SMILES: C=Cc1ccc(C(C)(c2ccc(C=C)cc2)C(C)(c2ccc(C=C)cc2)c2ccc(C=C)cc2)cc1]

### Synthesis Example 14: Compound of Formula (3-5)

In a reaction flask, 0.01 mol of 4-isopropylbenzaldehyde, 0.02 mol of N-bromosuccinimide, 0.05 mol of dibenzoyl peroxide and 10 ml of carbon tetrachloride were added and refluxed for 12 hours. After concentrated, the product was purified by a chromatography column to obtain 2-bromo-2-(4-formylphenyl)propane.

In a reaction flask, 0.01 mol of 2-bromo-2-(4-formylphenyl)propane and 0.02 mol of silver-activated zinc powder were added and reacted for 2 hours. The mixture was filtered to remove unreacted zinc powder and purified by a chromatography column to obtain 2,3-dimethyl-2,3-bis(4-formylphenyl)butane.

Tetrahydrofuran was added with anhydrous calcium chloride and stood still overnight to remove water. In a four-necked flask, 0.01 mol of 2,3-dimethyl-2,3-bis(4-formylphenyl)butane, 0.015 mol of methyltriphenylphosphonium bromide and 15 ml of tetrahydrofuran were added, and 0.015 mol of potassium tert-butoxide was added slowly under an iced water bath condition and reacted at room temperature for 2 hours. A saturated ammonium chloride aqueous solution was added to deactivate phosphorus ylides and filtered to remove excess salt to obtain a filtrate, which was added with 0.03 mol of calcium bromide, stirred for 18 hours and filtered so as to obtain a crude product, which was purified by a chromatography column to obtain 2,3-dimethyl-2,3-bis(4-vinylphenyl)butane, designated as a compound of Formula (3-5), as shown below.

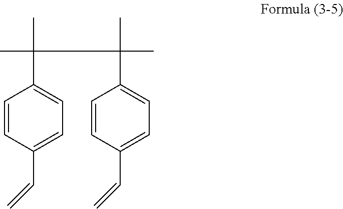 [SMILES: C=Cc1ccc(C(C)(C)C(C)(C)c2ccc(C=C)cc2)cc1]

### Synthesis Example 15: Compound of Formula (3-6)

Under nitrogen gas protection, 0.6 mol of acetophenone in a tetrahydrofuran solution was added to a three-necked flask, which was added dropwise with 1.8 mol of titanium tetrachloride in an iced bath. After the dropwise addition was completed, the reaction was stirred at room temperature for 10 minutes and refluxed for 12 hours. After the reaction was completed, as confirmed by TLC, it was cooled to room temperature and added with a potassium carbonate solution to precipitate. The precipitate was filtered to obtain a filter cake, which was then extracted with dichloromethane. Finally, the solvent was evaporated to obtain 0.25 mol of 1,2-dimethylstilbene.

In a three-necked flask, 0.24 mol of peroxybenzoate in a dichloromethane solution was added dropwise to 0.2 mol of 1,2-dimethylstilbene in a dichloromethane solution under an iced bath. After the dropwise addition was completed, the reaction was carried out at room temperature for 24 hours and completed, as confirmed by TLC. The organic phase was extracted with a sodium thiosulfate solution and a sodium bicarbonate solution in sequence, and the solvent was evaporated to obtain a dry powder solid, which was recrystallized by acetone to obtain 0.16 mol of 1,2-dimethylstilbene epoxide.

In a three-necked flask, 0.15 mol of 1,2-dimethylstilbene epoxide in a tetrahydrofuran solution was added, and 0.6 mol of a 10% sulfuric acid solution was added at room temperature. After refluxing for 8 hours, the reaction was completed. The reaction solution was poured into 5 liters of cold water to precipitate a solid, which was filtered to obtain a filter cake. After recrystallization by ethanol, 0.14 mol of 1,2-dimethyldiphenylbutanediol was obtained.

0.1 mol of 1,2-dimethyldiphenylbutanediol, 0.15 mol of methacryloyl chloride and toluene were added in such order to a three-necked flask equipped with a water separator, and 0.01 mol of concentrated sulfuric acid was added. After refluxing for 24 hours, the reaction solution was neutralized with a 10% sodium hydroxide solution, extracted with ethyl acetate and washed with saturated brine. The solvent was evaporated to obtain a dry powder solid, which was recrystallized by isopropanol/n-hexane to obtain 0.08 mol of 2,3-diphenylbutane-2,3-dimethylbis(2-methacrylate), designated as a compound of Formula (3-6), as shown below.

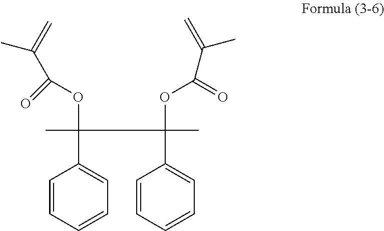 [SMILES: C=C(C)C(=O)OC(C)(c1ccccc1)C(C)(OC(=O)C(=C)C)c1ccccc1]

Compositions and test results of resin compositions of Examples and Comparative Examples used herein are listed in Table 1 to Table 5:

TABLE 1
Resin compositions of Examples (in part by weight) and test results

| Component | | E1 | E2 | E3 | E4 | E5 | E6 |
|---|---|---|---|---|---|---|---|
| copolymer | A1 | 100 | | | | | |
| | A2 | | 100 | | | | |
| | A3 | | | 100 | | | |
| | A4 | | | | 100 | | |
| | A5 | | | | | 100 | |
| | A6 | | | | | | 100 |
| | A7 | | | | | | |
| | A8 | | | | | | |
| | A9 | | | | | | |
| | A10 | | | | | | |
| | A11 | | | | | | |
| | B1 | | | | | | |
| | B2 | | | | | | |
| | B3 | | | | | | |
| | B4 | | | | | | |
| Compound of | Formula (3-1) | 5 | | | 5 | 5 | 5 |
| Formula (3) | Formula (3-2) | | 5 | | | | |
| | Formula (3-3) | | | 5 | | | |
| | Formula (3-4) | | | | | | |
| | Formula (3-5) | | | | | | |
| | Formula (3-6) | | | | | | |
| curing accelerator | DCP | | | | | | |
| different from the | 25B | | | | | | |
| compound of | 2E4MZ | | | | | | |
| Formula (3) | | | | | | | |
| polyolefin different | B-3000 | | | | | | |
| from the copolymer | Ricon 100 | | | | | | |
| | SBS-A | | | | | | |
| | H-1051 | | | | | | |
| unsaturated C═C | BVPE | | | | | | |
| double | | | | | | | |
| bond-containing | | | | | | | |
| crosslinking agent | | | | | | | |
| inorganic filler | SC-2500 SVJ | 100 | 100 | 100 | 100 | 100 | 100 |
| solvent | toluene | PA | PA | PA | PA | PA | PA |
| Item | Unit | E1 | E2 | E3 | E4 | E5 | E6 |
| glass transition | ° C. | 315 | 318 | 322 | 318 | 324 | 326 |
| temperature | | | | | | | |
| storage modulus | % | 11 | 11 | 10 | 11 | 10 | 9 |
| decay rate | | | | | | | |
| reflow warpage | μm | 9 | 9 | 8 | 9 | 8 | 7 |
| magnitude | | | | | | | |
| percent of thermal | % | 0.9 | 0.9 | 0.8 | 0.9 | 0.8 | 0.7 |
| expansion in Z-axis | | | | | | | |
| dissipation factor | none | 0.00076 | 0.00082 | 0.00086 | 0.00080 | 0.00082 | 0.00084 |
| laminate | none | pass | pass | pass | pass | pass | pass |
| appearance | | | | | | | |

TABLE 2
Resin compositions of Examples (in part by weight) and test results

| Component | | E7 | E8 | E9 | E10 | E11 | E12 |
|---|---|---|---|---|---|---|---|
| copolymer | A1 | | | | | | |
| | A2 | 100 | 100 | 100 | 100 | | |
| | A3 | | | | | 100 | |
| | A4 | | | | | | 100 |
| | A5 | | | | | | |
| | A6 | | | | | | |
| | A7 | | | | | | |
| | A8 | | | | | | |
| | A9 | | | | | | |
| | A10 | | | | | | |
| | A11 | | | | | | |
| | B1 | | | | | | |
| | B2 | | | | | | |
| | B3 | | | | | | |
| | B4 | | | | | | |
| Compound of | Formula (3-1) | 1 | 5 | 15 | | | |
| Formula (3) | Formula (3-2) | | | | | | |
| | Formula (3-3) | | | | | | |
| | Formula (3-4) | | | | 15 | | |
| | Formula (3-5) | | | | | 5 | |
| | Formula (3-6) | | | | | | 1 |
| curing accelerator | DCP | | | | | | |
| different from the | 25B | | | | | | |
| compound of | 2E4MZ | | | | | | |
| Formula (3) | | | | | | | |
| polyolefin different | B-3000 | | | | | | |
| from the copolymer | Ricon 100 | | | | | | |
| | SBS-A | | | | | | |
| | H-1051 | | | | | | |
| unsaturated C═C | BVPE | | | | | | |
| double | | | | | | | |
| bond-containing | | | | | | | |
| crosslinking agent | | | | | | | |
| inorganic filler | SC-2500 SVJ | 100 | 100 | 100 | 100 | 100 | 100 |
| solvent | toluene | PA | PA | PA | PA | PA | PA |
| Item | Unit | E7 | E8 | E9 | E10 | E11 | E12 |
| glass transition | ° C. | 312 | 316 | 328 | 348 | 339 | 333 |
| temperature | | | | | | | |
| storage modulus | % | 12 | 11 | 9 | 6 | 7 | 7 |
| decay rate | | | | | | | |
| reflow warpage | μm | 10 | 9 | 7 | 5 | 6 | 6 |
| magnitude | | | | | | | |
| percent of thermal | % | 0.9 | 0.9 | 0.7 | 0.6 | 0.6 | 0.7 |
| expansion in Z-axis | | | | | | | |
| dissipation factor | none | 0.00078 | 0.00079 | 0.00080 | 0.00080 | 0.00081 | 0.00079 |
| laminate | none | pass | pass | pass | pass | pass | pass |
| appearance | | | | | | | |

TABLE 3
Resin compositions of Examples (in part by weight) and test results

| Component | | E13 | E14 | E15 | E16 | E17 | E18 | E19 |
|---|---|---|---|---|---|---|---|---|
| copolymer | A1 | | | | | | | |
| | A2 | | | | | | 50 | 40 |
| | A3 | | | | | | | 20 |
| | A4 | | | | | | 20 | 10 |
| | A5 | | | | | | 20 | 10 |
| | A6 | | | | | | 10 | 20 |
| | A7 | 100 | | | | | | |
| | A8 | | 100 | | | | | |
| | A9 | | | 100 | | | | |
| | A10 | | | | 100 | | | |
| | A11 | | | | | 100 | | |
| | B1 | | | | | | | |
| | B2 | | | | | | | |
| | B3 | | | | | | | |
| | B4 | | | | | | | |
| Compound of | Formula (3-1) | 5 | 5 | 5 | 5 | 5 | 4 | |
| Formula (3) | Formula (3-2) | | | | | | | 2 |
| | Formula (3-3) | | | | | | | 2 |
| | Formula (3-4) | | | | | | | |
| | Formula (3-5) | | | | | | 4 | 3 |
| | Formula (3-6) | | | | | | | 3 |
| curing accelerator | DCP | | | | | | 2 | |
| different from the | 25B | | | | | | | |
| compound of | 2E4MZ | | | | | | | |
| Formula (3) | | | | | | | | |
| polyolefin different | B-3000 | | | | | | | |
| from the copolymer | Ricon 100 | | | | | | 10 | |
| | SBS-A | | | | | | | |
| | H-1051 | | | | | | | 5 |
| unsaturated C═C | BVPE | | | | | | 5 | 10 |
| double | | | | | | | | |
| bond-containing | | | | | | | | |
| crosslinking agent | | | | | | | | |
| inorganic filler | SC-2500 SVJ | 100 | 100 | 100 | 100 | 100 | 80 | 200 |
| solvent | toluene | PA | PA | PA | PA | PA | PA | PA |
| Item | Unit | E13 | E14 | E15 | E16 | E17 | E18 | E19 |
| glass transition | ° C. | 294 | 290 | 296 | 300 | 304 | 354 | 358 |
| temperature | | | | | | | | |
| storage modulus | % | 16 | 16 | 15 | 14 | 14 | 6 | 6 |
| decay rate | | | | | | | | |
| reflow warpage | μm | 14 | 14 | 13 | 12 | 12 | 5 | 5 |
| magnitude | | | | | | | | |
| percent of thermal | % | 1.2 | 1.2 | 1.2 | 1.1 | 1.1 | 0.6 | 0.6 |
| expansion in Z-axis | | | | | | | | |
| dissipation factor | none | 0.00086 | 0.00079 | 0.00083 | 0.00084 | 0.00086 | 0.00070 | 0.00070 |
| laminate | none | pass | pass | pass | pass | pass | pass | pass |
| appearance | | | | | | | | |

TABLE 4
Resin compositions of Comparative Examples (in part by weight) and test results

| Component | | C1 | C2 | C3 | C4 | C5 | C6 |
|---|---|---|---|---|---|---|---|
| copolymer | A1 | | | | | | |
| | A2 | 100 | 100 | | | | |
| | A3 | | | | | | |
| | A4 | | | | | | |
| | A5 | | | | | | |
| | A6 | | | | | | |
| | A7 | | | | | | |
| | A8 | | | | | | |
| | A9 | | | | | | |
| | A10 | | | | | | |
| | A11 | | | | | | |
| | B1 | | | 100 | | | |
| | B2 | | | | 100 | | |
| | B3 | | | | | 100 | |
| | B4 | | | | | | 100 |
| Compound of | Formula (3-1) | 0 | 20 | 5 | 5 | 5 | 5 |
| Formula (3) | Formula (3-2) | | | | | | |
| | Formula (3-3) | | | | | | |
| | Formula (3-4) | | | | | | |
| | Formula (3-5) | | | | | | |
| | Formula (3-6) | | | | | | |
| curing accelerator | DCP | | | | | | |
| different from the | 25B | | | | | | |
| compound of | 2E4MZ | | | | | | |
| Formula (3) | | | | | | | |
| polyolefin different | B-3000 | | | | | | |
| from the copolymer | Ricon 100 | | | | | | |
| | SBS-A | | | | | | |
| | H-1051 | | | | | | |
| unsaturated C═C | BVPE | | | | | | |
| double | | | | | | | |
| bond-containing | | | | | | | |
| crosslinking agent | | | | | | | |
| inorganic filler | SC-2500 SVJ | 100 | 100 | 100 | 100 | 100 | 100 |
| solvent | toluene | PA | PA | PA | PA | PA | PA |
| Item | Unit | C1 | C2 | C3 | C4 | C5 | C6 |
| glass transition | ° C. | 261 | 324 | 286 | 276 | 323 | 281 |
| temperature | | | | | | | |
| storage modulus | % | 20 | 22 | 17 | 19 | 10 | 19 |
| decay rate | | | | | | | |
| reflow warpage | μm | 18 | 16 | 12 | 13 | 8 | 12 |
| magnitude | | | | | | | |
| percent of thermal | % | 1.2 | 0.7 | 1.1 | 1.2 | 0.8 | 1.1 |
| expansion in Z-axis | | | | | | | |
| dissipation factor | none | 0.00080 | 0.00080 | 0.00076 | 0.00072 | 0.00096 | 0.00084 |
| laminate | none | pass | pass | pass | pass | NG | pass |
| appearance | | | | | | | |

TABLE 5
Resin compositions of Comparative Examples (in part by weight) and test results

| Component | | C7 | C8 | C9 | C10 | C11 | C12 | C13 |
|---|---|---|---|---|---|---|---|---|
| copolymer | A1 | | | | | | | |
| | A2 | | | | | 100 | 100 | 100 |
| | A3 | | | | | | | |
| | A4 | | | | | | | |
| | A5 | | | | | | | |
| | A6 | | | | | | | |
| | A7 | | | | | | | |
| | A8 | | | | | | | |
| | A9 | | | | | | | |
| | A10 | | | | | | | |
| | A11 | | | | | | | |
| | B1 | | | | | | | |
| | B2 | | | | | | | |
| | B3 | | | | | | | |
| | B4 | | | | | | | |
| Compound of | Formula (3-1) | 5 | 5 | 5 | 5 | | | |
| Formula (3) | Formula (3-2) | | | | | | | |
| | Formula (3-3) | | | | | | | |
| | Formula (3-4) | | | | | | | |
| | Formula (3-5) | | | | | | | |
| | Formula (3-6) | | | | | | | |
| curing accelerator | DCP | | | | | 5 | | |
| different from the | 25B | | | | | | 5 | |
| compound of | 2E4MZ | | | | | | | 5 |
| Formula (3) | | | | | | | | |
| polyolefin different | B-3000 | 100 | | | | | | |
| from the copolymer | Ricon 100 | | 100 | | | | | |
| | SBS-A | | | 100 | | | | |
| | H-1051 | | | | 100 | | | |
| unsaturated C═C | BVPE | | | | | | | |
| double | | | | | | | | |
| bond-containing | | | | | | | | |
| crosslinking agent | | | | | | | | |
| inorganic filler | SC-2500 SVJ | 100 | 100 | 100 | 100 | 100 | 100 | 100 |
| solvent | toluene | PA | PA | PA | PA | PA | PA | PA |
| Item | Unit | C7 | C8 | C9 | C10 | C11 | C12 | C13 |
| glass transition | ° C. | <110 | <110 | <110 | <110 | 274 | 282 | 239 |
| temperature | | | | | | | | |
| storage modulus | % | 81 | 84 | 81 | 90 | 20 | 18 | 26 |
| decay rate | | | | | | | | |
| reflow warpage | μm | 30 | 35 | 34 | 38 | 13 | 11 | 19 |
| magnitude | | | | | | | | |
| percent of thermal | % | 2.5 | 2.7 | 2.6 | 2.9 | 1.2 | 1.1 | 1.5 |
| expansion in Z-axis | | | | | | | | |
| dissipation factor | none | 0.00091 | 0.00092 | 0.00090 | 0.00091 | 0.00114 | 0.00106 | 0.00146 |
| laminate | none | NG | NG | NG | NG | pass | pass | pass |
| appearance | | | | | | | | |

According to the present disclosure, for the property tests of Examples and Comparative Examples, samples (specimens) were prepared as described below and tested under specified conditions below.

1. Prepreg A: Resin composition from each Example or each Comparative Example was individually well-mixed to form a varnish, which was then loaded to an impregnation tank; a fiberglass fabric (e.g., 2116 L-glass fiber fabric) was impregnated into the impregnation tank to adhere the resin composition onto the fiberglass fabric, followed by heating at 150° C. to 170° C. to a semi-cured stage (B-stage) to obtain a prepreg with a resin content of 53%.

2. Prepreg B: Resin composition from each Example or each Comparative Example was individually well-mixed to form a varnish, which was then loaded to an impregnation tank; a fiberglass fabric (e.g., 1080 quartz glass fiber fabric) was impregnated into the impregnation tank to adhere the resin composition onto the fiberglass fabric, followed by heating at 150° C. to 170° C. to a semi-cured stage (B-stage) to obtain a prepreg with a resin content of 70%.

3. Copper-clad laminate (8-ply, formed by lamination of eight prepregs): Two 18 μm hyper very low profile (HVLP) copper foils and eight Prepregs A obtained from 2116 L-glass fiber fabrics impregnated with each Example or each Comparative Example and having a resin content of about 53% were prepared and stacked in the order of one HVLP copper foil, eight prepregs and one HVLP copper foil, followed by lamination under vacuum at 500 psi and 200° C. for 2 hours to form a copper-clad laminate. Insulation layers between the two copper foils were formed by laminating and curing eight sheets of prepreg, and the resin content of the insulation layers is about 53%.

4. Copper-free laminate (8-ply, formed by lamination of eight prepregs): Each aforesaid copper-clad laminate (8-ply) was etched to remove the two copper foils to obtain a copper-free laminate (8-ply), which is formed by laminating eight sheets of prepreg and has a resin content of about 53%.

5. Copper-free laminate (2-ply, formed by lamination of two prepregs): Two 18 μm hyper very low profile (HVLP) copper foils and two Prepregs B obtained from 1080 quartz glass fiber fabrics impregnated with each Example or Comparative Example were prepared and stacked in the order of one copper foil, two prepregs and one copper foil, followed by lamination under vacuum at 500 psi and 200° C. for 2 hours to form a copper-clad laminate (2-ply, formed by lamination of two prepregs). Next, each copper-clad laminate (2-ply) was etched to remove the copper foils on both sides to obtain a copper-free laminate (2-ply) which is formed by laminating two prepregs and has a resin content of about 70%.

6. Ten-layer board: An EM-LX copper-containing laminate (available from Elite Material Co., Ltd., 3 mil in thickness, using 1078 E-glass fiber fabric and 18 μm HTE copper foil) was subjected to trace formation processes on the surface of copper foils, including such as conventional exposure, lithography, etching, etc., to obtain a core. After obtaining the core, preparing a Prepreg C from the resin composition of each Example or Comparative Example using 1027 L-glass fiber fabric; placing a Prepreg C on both sides of the core and covering a 18 μm HTE copper foil on the other side of the Prepreg C opposite to the core, followed by lamination and curing in vacuum at high temperature (200° C.) and high pressure (360 psi) for 2 hours to complete the first lamination. After that, a drilling process was performed to make alignment holes, and then hole metallization process and trace formation process were performed to complete the first build-up step to obtain a four-layer board. The build-up processes were repeated to form a six-layer board (second build-up, second lamination), an eight-layer board (third build-up, third lamination), and finally a ten-layer board (fourth build-up, fourth lamination).

For each sample, test items and test methods are described below.

### 1. Glass Transition Temperature (Tg)

Each copper-free laminate (8-ply) sample was subjected to the measurement of glass transition temperature (in ° C.) by using a dynamic mechanical analyzer (DMA) by reference to IPC-TM-650 2.4.24.4 (2012). Temperature interval during the measurement was set at 50° C. to 400° C. with a temperature increase rate of 2° C./minute.

### 2. Storage Modulus Decay Rate

The copper-free laminate (8-ply) sample was subjected to the measurement of storage modulus using a dynamic mechanical analyzer (DMA) by reference to IPC-TM-650 2.4.24.4, wherein the temperature interval during the measurement was set at 50° C. to 400° C. with a temperature increase rate of 2° C./minute. The storage modulus (in MPa) of the sample at 50° C. is recorded and designated as E′₅₀, and the storage modulus (in MPa) of the sample at 250° C. is recorded and designated as E′₂₅₀. The storage modulus decay rate can be calculated as follow: ((E′₅₀−E′₂₅₀)/E′₅₀)*100%. A relative difference in storage modulus decay rate of greater than or equal to 1% represents a substantial difference (i.e., significant technical difficulty) between different samples.

### 3. Reflow Warpage Magnitude

The ten-layer board was cut into a sample with a size of 150 mm*78 mm, which was tested by using a TherMoire apparatus sold by Akrometrix by reference to JESD22-B112A and subjected to a reflow process, during which the temperature was raised from 30° C. to 260° C. such that the maximum warpage and minimum warpage of the ten-layer board at 260° C. and 30° C. were measured. The difference (in μm) is the reflow warpage magnitude (i.e., the maximum warpage minus the minimum warpage). A reflow warpage magnitude of greater than or equal to 1 μm represents a substantial difference (i.e., significant technical difficulty) in different samples.

### 4. Percent of Thermal Expansion in Z-Axis (Z-PTE)

The copper-free laminate (8-ply) sample was subjected to thermal mechanical analysis (TMA) by reference to IPC-TM-650 2.4.24.5. Each sample was heated from 50° C. to 260° C. at a heating rate of 10° C./minute and then subjected to the measurement of percent (%) of thermal expansion in Z-axis in a temperature range of 50° C. to 260° C. When the test values of percent of thermal expansion in Z-axis are less than or equal to 1%, a difference in the test values of percent of thermal expansion in Z-axis of greater than or equal to 0.1% represents a substantial difference (i.e., significant technical difficulty) in different samples. For example, the difference in the test values of Example E1 and Comparative Example C1 of the present disclosure is 1.2%-0.9%=0.3%, representing a substantial difference between E1 and C1; on the other hand, compared to Comparative Example C1, the percent of thermal expansion in Z-axis of Example E1 is improved by (0.3%/1.2%)*100%=25%; that is, compared to Comparative Example C1, the percent of thermal expansion in Z-axis of Example E1 is reduced by 25%.

### 5. Dissipation Factor (Df)

The copper-free laminate (2-ply) sample was tested by using a microwave dielectrometer available from AET Corp. by reference to JIS C2565 (1992) at 10 GHz at room temperature (about 25° C.). Under a 10 GHz frequency, for a Df value of less than 0.001, a difference in Df values greater than or equal to 0.00002 represents a substantial difference in dissipation factor in different laminates (i.e., significant technical difficulty).

### 6. Laminate Appearance

The copper-free laminate (8-ply, formed by lamination of eight prepregs) was subjected to visual inspection to determine whether a branch-like pattern (abbreviated as “pattern”) is present on the surface edges of the laminate appearance; absence of branch-like patterns on its edges, as illustrated in FIG. 6 of U.S. Pat. No. 11,434,367 B2, is designated as “pass”, and presence of branch-like patterns on its edges, as illustrated in FIG. 4 of U.S. Pat. No. 11,434,367 B2, is designated as “NG”.

The following observations can be made from Table 1 to Table 5:

1. In Examples E1 to E19, the copolymer having a structural unit formed by a monomer of Formula (1) and a structural unit formed by a monomer of Formula (2) is used, wherein the monomer of Formula (1) may be, for example, styrene (St), ethylvinylbenzene, divinylbenzene (DVB) or bis(vinylphenyl)ethane (BVPE), the monomer of Formula (2) may be, for example, 4-vinylbenzocyclobutene (VBCB), and the content of the structural unit formed by the monomer of Formula (2) in the copolymer is 55 wt % to 90 wt %. The copolymers of Examples E1 to E12 and E18 to E19 are block copolymers, and the copolymers of Examples E13 to E17 are random copolymers. In Comparative Examples C1 and C2, the amount of a compound of Formula (3) is not within the range of the present disclosure; in the copolymers of Comparative Examples C3 and C4, the structural unit formed by a monomer of Formula (2) is not within the range of the present disclosure (VBCB content in C3 is 50 wt %, and VBCB content in C4 is 30 wt %); in Comparative Example C5, VBCB homopolymer is used (VBCB content is 100 wt %); in Comparison Example C6, a BCB-modified DVB-St copolymer different from the copolymer of the present disclosure is used; in Comparative Examples C7 to C10, a polyolefin different from the copolymer of the present disclosure is used; and in Comparative Examples C11 to C13, a curing accelerator different from the compound of Formula (3) is used.

2. If 100 parts by weight of a copolymer of the present disclosure is used in conjunction with 1 to 15 parts by weight of a compound of Formula (3), such as Examples E1 to E19, in contrast to 100 parts by weight of a copolymer of the present disclosure used in conjunction with 0 part by weight and 20 parts by weight of a compound of Formula (3) respectively in Comparative Examples C1 and C2, significant improvements in the following properties will be achieved: storage modulus decay rate and reflow warpage magnitude, wherein all samples in Examples E1 to E19 have a storage modulus decay rate of less than or equal to 16% and a reflow warpage magnitude of less than or equal to 14 μm; in contrast, both Comparative Examples C1 and C2 have a storage modulus decay rate of greater than or equal to 20% and a reflow warpage magnitude of greater than or equal to 16 μm.

3. If a copolymer of the present disclosure is used in conjunction with a compound of Formula (3), such as Examples E1 to E19, in contrast to a copolymer having VBCB content not within the range of the present disclosure used in conjunction with a compound of Formula (3), such as Comparative Examples C3 and C4, and a BCB-modified DVB-St copolymer different from the copolymer of the present disclosure used in conjunction with a compound of Formula (3), such as Comparative Example C6, significant improvements in the following property will be achieved: storage modulus decay rate, wherein all samples in Examples E1 to E19 have a storage modulus decay rate of less than or equal to 16%, and all samples in Comparative Examples C3, C4 and C6 have a storage modulus decay rate of greater than or equal to 17%. In addition, if a copolymer of the present disclosure is used and added with a compound of Formula (3), such as Examples E1 to E19, in contrast to a VBCB homopolymer (VBCB content is 100 wt %) used and added with a compound of Formula (3), such as Comparative Example C5, significant improvements in the following properties will be achieved: dissipation factor and laminate appearance, wherein all samples in Examples E1 to E19 have a dissipation factor of less than or equal to 0.00086 and are absent of patterns on laminate appearance, and Comparative Example C5 has a dissipation factor of 0.00096 and is present of patterns on laminate appearance.

4. If a copolymer of the present disclosure is used in conjunction with a compound of Formula (3), such as Examples E1 to E19, in contrast to a polyolefin different from the copolymer of the present disclosure used in conjunction with a compound of Formula (3), such as Comparative Examples C7 to C10, significant improvements in the following properties will be achieved: glass transition temperature, storage modulus decay rate, reflow warpage magnitude degree, percent of thermal expansion in Z-axis, dissipation factor and laminate appearance, wherein all samples in Examples E1 to E19 have a glass transition temperature of greater than or equal to 290° C., a storage modulus decay rate of less than or equal to 16%, a reflow warpage magnitude of less than or equal to 14 μm, a percent of thermal expansion in Z-axis of less than or equal to 1.2% and a dissipation factor of less than or equal to 0.00086, and are absent of patterns on laminate appearance; in contrast, all Comparative Examples C7 to C10 have a glass transition temperature of less than 110° C., a storage modulus decay rate of greater than or equal to 81%, a reflow warpage magnitude of greater than or equal to 30 μm, a percent of thermal expansion in Z-axis of greater than or equal to 2.5% and a dissipation factor of greater than or equal to 0.00090, and are present of patterns on laminate appearance.

5. If a copolymer of the present disclosure is used in conjunction with a compound of Formula (3), such as Examples E1 to E19, in contrast to a copolymer of the present disclosure used in conjunction with a curing accelerator different from the compound of Formula (3), such as Comparative Examples C11 to C13, significant improvements in the following properties will be achieved: storage modulus decay rate and dissipation factor, wherein all samples in Examples E1 to E19 have a storage modulus decay rate of less than or equal to 16% and a dissipation factor of less than or equal to 0.00086; in contrast, all Comparative Examples C11 to C13 have a storage modulus decay rate of greater than or equal to 18% and a dissipation factor of greater than or equal to 0.00106.

6. If a copolymer of the present disclosure used is a block copolymer in conjunction with a compound of Formula (3), such as Examples E1 to E12 and E18 to E19, in contrast to using a random copolymer as a copolymer of the present disclosure in conjunction with a compound of Formula (3), such as Examples E13 to E17, significant improvements in each property will be achieved, especially having lower storage modulus decay rate, lower percent of thermal expansion in Z-axis and the smaller reflow warpage magnitude.

The above detailed description is merely illustrative in nature and is not intended to limit the embodiments of the subject matter or the applications and uses of such embodiments. As used herein, the term “exemplary” or similar expression means “serving as an example, instance, or illustration.” Any implementation described herein as exemplary is not necessarily to be construed as preferred or advantageous over other implementations, unless otherwise specified.

Moreover, while at least one exemplary example or comparative example has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments and equivalents thereof. Also, the scope defined by the claims includes known equivalents and foreseeable equivalents at the time of filing this patent application.

What is claimed is:

1. A resin composition, comprising:
(A) 100 parts by weight of a copolymer, the copolymer having a structural unit formed by a monomer of Formula (1) and a structural unit formed by a monomer of Formula (2), and the content of the structural unit formed by the monomer of Formula (2) in the copolymer is 55 wt % to 90 wt %; and
(B) 1 part by weight to 15 parts by weight of a compound of Formula (3); 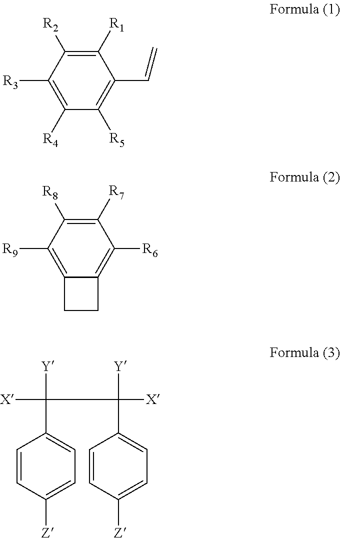
in Formula (1), R₁ to R₅ are each independently selected from a hydrogen atom, a C1 to C3 alkyl group, a C2 to C3 alkenyl group, a phenyl group, a phenyl group substituted by a C1 to C3 alkyl group, a phenyl group substituted by a C2 to C3 alkenyl group and a C2 to C3 alkenyl phenyl C1 to C3 alkylene group;
in Formula (2), R₆ to R₉ are each independently selected from a hydrogen atom, a C1 to C3 alkyl group and a C2 to C3 alkenyl group, and at least one of R₆ to R₉ is a C2 to C3 alkenyl group;
in Formula (3), each X′, Y′ and Z′ independently represent a hydrogen atom, a C1 to C4 alkyl group, a phenyl group, or an unsaturated C═C double bond-containing group.

2. The resin composition of claim 1, wherein the monomer of Formula (1) comprises a monomer of Formula (1-1), a monomer of Formula (1-2), a monomer of Formula (1-3), a monomer of Formula (1-4) or a combination thereof, and the monomer of Formula (2) comprises a monomer of Formula (2-1),

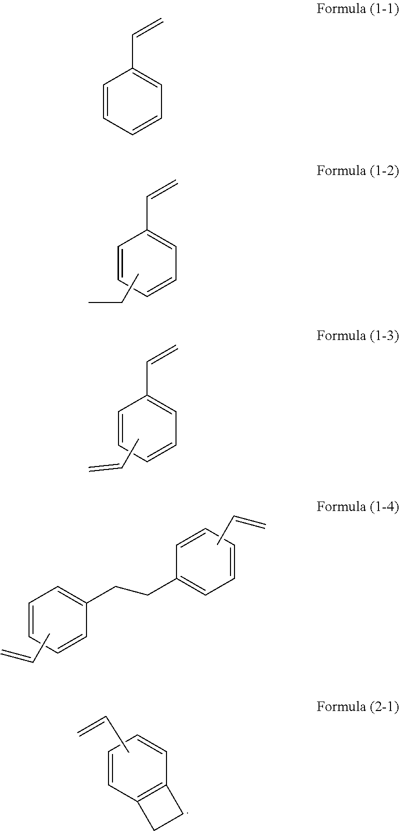

3. The resin composition of claim 1, wherein the copolymer comprises any one of a copolymer of Formula (4) to a copolymer of Formula (19) below or a combination thereof: 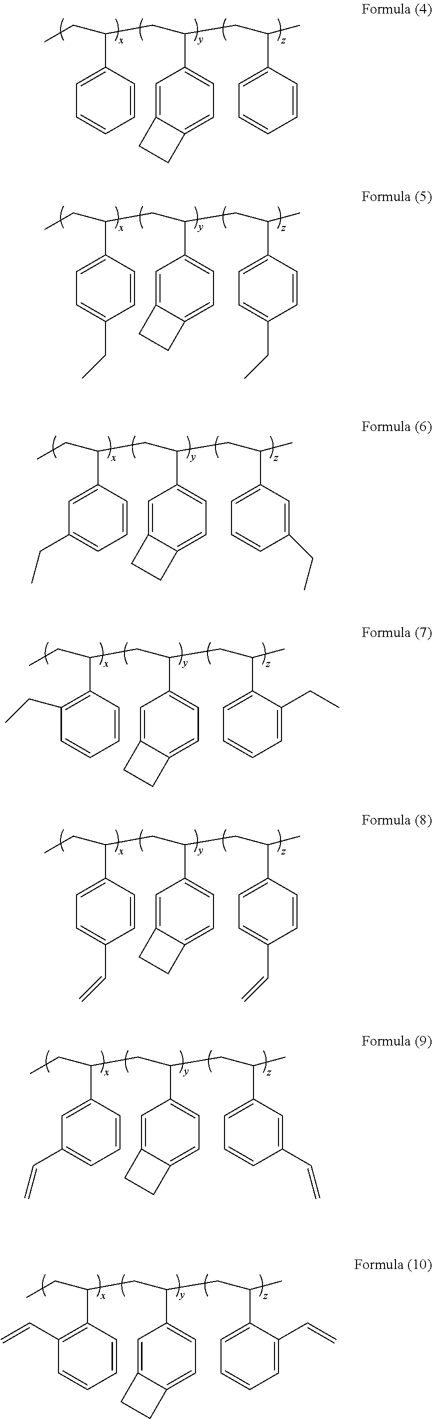 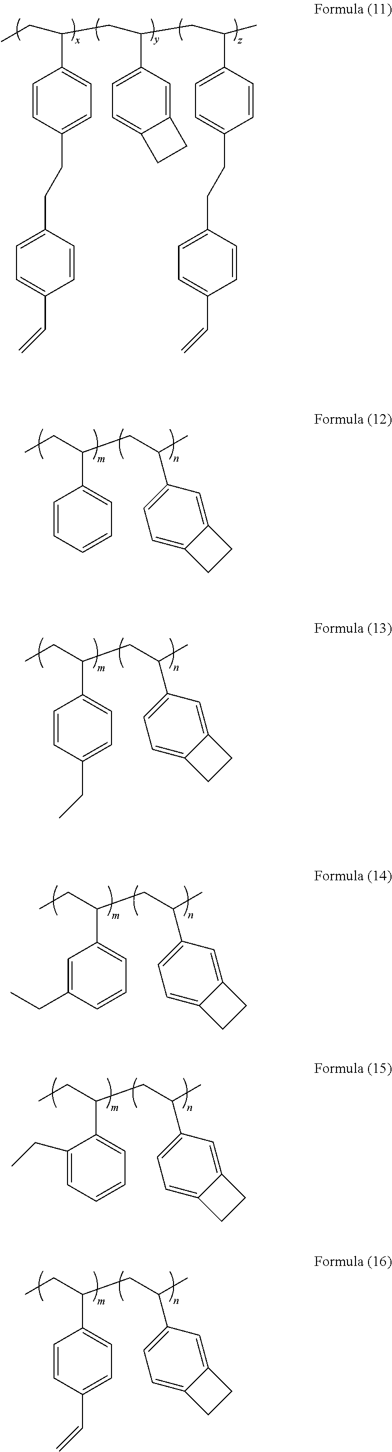 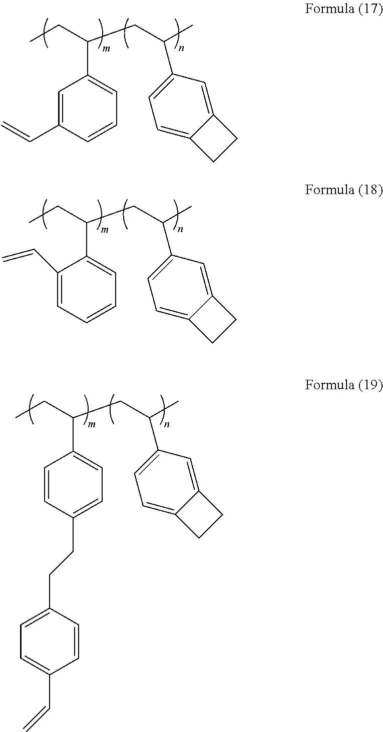
wherein m, n, x, y and z are each independently a positive integer, 2≤m≤44, 12≤n≤70, 2≤x+z≤44, and 12≤y≤70.

4. The resin composition of claim 1, wherein the copolymer comprises a block copolymer, a random copolymer or a combination thereof.

5. The resin composition of claim 1, wherein the compound of Formula (3) has at least one unsaturated C═C double bond-containing group.

6. The resin composition of claim 1, wherein, in Formula (3), at least one of X′, Y′ and Z′ represents a vinyl group, a vinylbenzyl group, a vinylphenyl group, an allyl group or a (meth)acryloyloxy group.

7. The resin composition of claim 1, wherein the compound of Formula (3) comprises any one of a compound of Formula (3-1) to a compound of Formula (3-6) or a combination thereof:

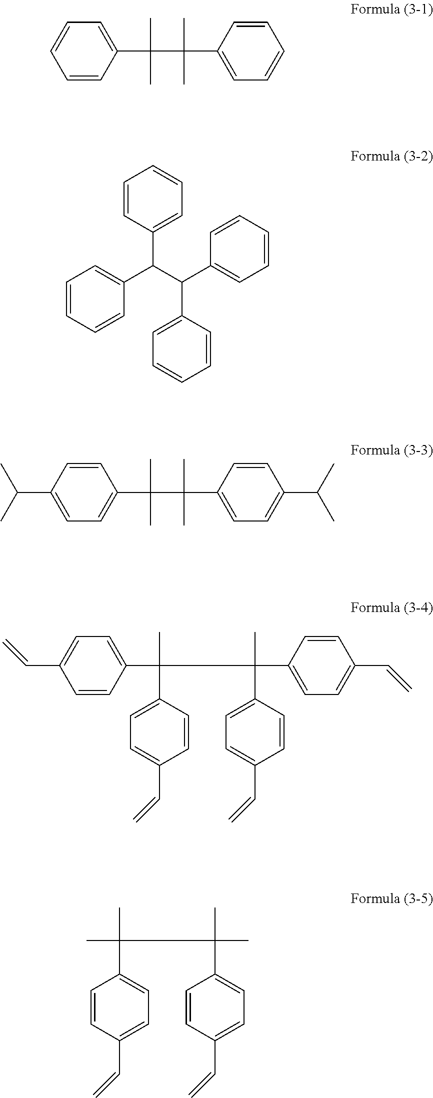

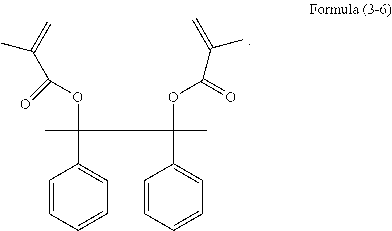 [SMILES: C=C(C)C(=O)OC(C)(c1ccccc1)C(C)(OC(=O)C(=C)C)c1ccccc1]

8. The resin composition of claim 1, further comprising an unsaturated C═C double bond-containing crosslinking agent selected from any one of bis(vinylphenyl)ethane, divinylbenzene, divinylnaphthalene, divinylbiphenyl, triallyl isocyanurate, triallyl cyanurate, vinylbenzocyclobutene, bis(vinylbenzyl)ether, trivinyl cyclohexane, diallyl bisphenol A, acrylate with two or more functional groups, butadiene, decadiene and octadiene or a combination thereof.

9. The resin composition of claim 1, further comprising a polyolefin different from the copolymer, an unsaturated C═C double bond-containing polyphenylene ether resin, a benzoxazine resin, an epoxy resin, a polyester resin, a phenol resin, an amine curing agent, a polyamide, a polyimide, a styrene maleic anhydride, a maleimide resin, a cyanate ester or a combination thereof.

10. The resin composition of claim 1, further comprising an inorganic filler, a flame retardant, a curing accelerator different from the compound of Formula (3), a polymerization inhibitor, a solvent, a silane coupling agent, a coloring agent, a toughening agent or a combination thereof.

11. An article made from the resin composition of claim 1, wherein the article comprises a prepreg, a resin film, a laminate, or a printed circuit board.

12. The article of claim 11, which has a glass transition temperature as measured by reference to IPC-TM-650 2.4.24.4 of greater than or equal to 290° C.

13. The article of claim 11, which has a storage modulus decay rate as measured and calculated by reference to IPC-TM-650 2.4.24.4 of less than or equal to 16%.

14. The article of claim 11, which has a reflow warpage magnitude as measured by reference to JESD22-B112A of less than or equal to 14 μm.

15. The article of claim 11, which has a percent of thermal expansion in Z-axis as measured by reference to IPC-TM-650 2.4.24.5 of less than or equal to 1.2%.

16. The article of claim 11, which has a dissipation factor as measured by reference to JIS C2565 at 10 GHz of less than or equal to 0.00086.
